(19) United States
(12) Patent Application Publication
(10) Pub. No.: US 2026/0033212 A1
(43) Pub. Date: Jan. 29, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Chi YU, Beijing (CN); Zhenhua ZHANG, Beijing (CN); Jianpeng WU, Beijing (CN); Ming HU, Beijing (CN); Zhiliang JIANG, Beijing (CN); Ge WANG, Beijing (CN); Tong WU, Beijing (CN)

(21) Appl. No.: 18/993,555

(22) PCT Filed: Apr. 16, 2024
(86) PCT No.: PCT/CN2024/088009

§ 371 Date: Jan. 12, 2025

(30) Foreign Application Priority Data
May 30, 2023 (CN) 202310632289.8

(51) Int. Cl. H10K 59/80; H10K 59/122; H10K 59/35

(52) U.S. Cl. CPC H10K 59/80521; H10K 59/122; H10K 59/352; H10K 59/353

(57) ABSTRACT

The embodiment of the present disclosure provides a display substrate, including: a base substrate; a pixel defining layer on a side of the base substrate and including a plurality of pixel openings; a plurality of support patterns on a side of the pixel defining layer away from the base substrate; and a cathode layer on a side of the pixel defining layer away from the base substrate, and including a plurality of hollowed-out structures, and an orthographic projection of the plurality of hollowed-out structures on the base substrate does not overlap with an orthographic projection of the plurality of pixel openings on the base substrate. The present disclosure further provides a display apparatus.

### TECHNICAL FIELD

The present disclosure relates to the field of display technology, and in particular to a display substrate and a display apparatus.

### BACKGROUND

With the development of technology, a display panel in a display apparatus is generally required to have a certain light transmittance.

In a scenario, the display apparatus may be a full-screen display apparatus, and a photosensitive sensor, such as a light sensor and a distance sensor, in the display apparatus is required to be located on a back side of the display panel (i.e., a side opposite to a display surface of the display panel). In order not to affect the normal operation of the photosensitive component, it is necessary to ensure that a region opposite to the photosensitive component in the display panel has a certain light transmittance. In another scenario, the display apparatus may be a transparent display apparatus, and all regions in the display panel of the display apparatus are required to have a certain light transmittance.

### SUMMARY

In a first aspect, an embodiment of the present disclosure provides a display substrate, including: a base substrate; a pixel defining layer on a side of the base substrate and including a plurality of pixel openings; a plurality of support patterns on a side of the pixel defining layer away from the base substrate; and a cathode layer on a side of the pixel defining layer away from the base substrate, and including a plurality of hollowed-out structures, and an orthographic projection of the plurality of hollowed-out structures on the base substrate does not overlap with an orthographic projection of the plurality of pixel openings on the base substrate.

In some embodiments, the orthographic projection of the plurality of hollowed-out structures on the base substrate does not overlap with an orthographic projection of the plurality of support patterns on the base substrate.

In some embodiments, the display substrate further includes: a plurality of cathode selection patterns in one-to-one correspondence with the plurality of hollowed-out structures, and an orthographic projection of each cathode selection pattern on the base substrate at least partially overlaps with an orthographic projection of the corresponding hollowed-out structure on the base substrate.

In some embodiments, an area of an orthographic projection of each of at least a part of the plurality of cathode selection patterns on the base substrate is greater than an area of an orthographic projection of each support pattern on the base substrate.

In some embodiments, the display substrate includes a first display region and a second display region at the periphery of the first display region, the plurality of hollowed-out structures and the plurality of cathode selection patterns are in the first display region, and a light transmittance of the first display region is greater than that of the second display region.

In some embodiments, the plurality of support patterns are in the second display region and not in the first display region.

In some embodiments, the plurality of support patterns are uniformly distributed in the second display region; or the second display region includes: a first sub-region close to and surrounding the first display region and a second sub-region on a side of the first sub-region away from the first display region, and a density of support patterns in the first sub-region is greater than that of support patterns in the second sub-region.

In some embodiments, support patterns are in the first display region.

In some embodiments, the display substrate further includes: a plurality of first repeating units in the first display region and in an array along a first direction and a second direction, wherein each first repeating unit includes a plurality of sub-pixels, and each of at least a part of the plurality of first repeating units is configured with support patterns; and a ratio of the number of sub-pixels in each first repeating unit configured with the support patterns to the number of the support patterns in the same first repeating unit is greater than or equal to 2 and less than or equal to 8.

In some embodiments, the display substrate further includes: a plurality of first repeating units in the first display region and in an array along a first direction and a second direction, wherein each first repeating unit includes a plurality of sub-pixels, and each of at least a part of the plurality of first repeating units is configured with cathode selection patterns; and a ratio of the number of sub-pixels in each first repeating unit configured with the cathode selection patterns to the number of the cathode selection patterns in the same first repeating unit is greater than or equal to 2 and less than or equal to 8.

In some embodiments, the display substrate further includes: a plurality of first repeating units in the first display region and in an array along a first direction and a second direction, wherein each first repeating unit includes two first sub-pixels and two second sub-pixels, pixel openings corresponding to the two first sub-pixels are first pixel openings, and pixel openings corresponding to the two second sub-pixels are second pixel openings; in each first repeating unit, patterns of orthographic projections of the first pixel openings of the two first sub-pixels on the base substrate are a first pattern and a third pattern, respectively, patterns of orthographic projections of the second pixel openings of the two second sub-pixels on the base substrate are a second pattern and a fourth pattern, respectively, and centers of the first pattern, the second pattern, the third pattern and the fourth pattern are a first center, a second center, a third center and a fourth center, respectively, which are sequentially connected to form a first quadrangle corresponding to the first repeating unit, and at least one of the plurality of first repeating units is configured with corresponding cathode selection patterns, an orthographic projection of the at least one cathode selection pattern corresponding to each first repeating unit on the base substrate overlaps with a region surrounded by the first quadrangle corresponding to the first repeating unit.

In some embodiments, in each first repeating unit, an extending direction of a line connecting the first center and the fourth center is parallel to the second direction, and an extending direction of a line connecting the second center and the third center is parallel to the second direction; a minimum distance between the first pattern and the fourth pattern is greater than a minimum distance between the second pattern and the third pattern; the corresponding cathode selection patterns configured by the first repeating unit include: at least one of a first cathode selection pattern and a second cathode selection pattern; an orthographic projection of the first cathode selection pattern on the base substrate is between the first pattern in the corresponding first repeating unit and the fourth pattern in the corresponding first repeating unit; and an orthographic projection of the second cathode selection pattern on the base substrate is between the third pattern in the corresponding first repeating unit and a second pattern adjacent to the third pattern in the second direction and in an adjacent first repeating unit.

In some embodiments, in each first repeating unit, a ratio of a distance between the first center and the fourth center to a distance between the second center and the third center is greater than 1 and less than or equal to 1.2.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the first cathode selection pattern on the base substrate is between the fifth pattern in the corresponding first repeating unit and a sixth pattern adjacent to the fifth pattern in the first direction and in an adjacent first repeating unit; and the orthographic projection of the second cathode selection pattern on the base substrate is between the seventh pattern in the corresponding first repeating unit and the eighth pattern in the corresponding first repeating unit.

In some embodiments, in each first repeating unit, an extending direction of a line connecting the fifth center and the sixth center is parallel to the first direction, and an extending direction of a line connecting the seventh center and the eighth center is parallel to the first direction; and a minimum distance between the fifth pattern and the sixth pattern is smaller than a minimum distance between the seventh pattern and the eighth pattern.

In some embodiments, in each first repeating unit, a ratio of a distance between the seventh center and the eighth center to a distance between the fifth center and the sixth center is greater than 1 and equal to or less than 1.2.

In some embodiments, at least one first repeating unit is configured with at least one corresponding support pattern; the corresponding support patterns configured by each first repeating unit include: at least one of a first support pattern and a second support pattern; an orthographic projection of the first support pattern on the base substrate is between the second pattern in the corresponding first repeating unit and the third pattern in the corresponding first repeating unit; and an orthographic projection of the second support pattern on the base substrate is between the fourth pattern in the corresponding first repeating unit and a first pattern adjacent to the fourth pattern in the second direction and in an adjacent first repeating unit.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the first support pattern on the base substrate is between the fifth pattern in the corresponding first repeating unit and the sixth pattern in the corresponding first repeating unit; and the orthographic projection of the second support pattern on the base substrate is between the eighth pattern in the corresponding first repeating unit and a seventh pattern adjacent to the eighth pattern in the first direction and in an adjacent first repeating unit.

In some embodiments, in each first repeating unit, a minimum distance between the second pattern and the third pattern is greater than a minimum distance between the second pattern and the first pattern; a minimum distance between the fourth pattern and the third pattern is greater than a minimum distance between the fourth pattern and the first pattern; the corresponding cathode selection patterns configured by each first repeating unit include: at least one of an eleventh cathode selection pattern, a twelfth cathode selection pattern, a thirteenth cathode selection pattern, and a fourteenth cathode selection pattern; an orthographic projection of the eleventh cathode selection pattern on the base substrate is between the second pattern in the corresponding first repeating unit and a first pattern adjacent to the second pattern in the first direction and in an adjacent first repeating unit; an orthographic projection of the twelfth cathode selection pattern on the base substrate is between the second pattern in the corresponding first repeating unit and the third pattern in the corresponding first repeating unit; an orthographic projection of the thirteenth cathode selection pattern on the base substrate is between the third pattern in the corresponding first repeating unit and the fourth pattern in the corresponding first repeating unit; and an orthographic projection of the fourteenth cathode selection pattern on the base substrate is between the fourth pattern in the corresponding first repeating unit and a first pattern adjacent to the fourth pattern in the second direction and in an adjacent first repeating unit.

In some embodiments, in each first repeating unit, a ratio of a distance between the second center and the third center to a distance between the second center and the first center is greater than 1 and less than or equal to 1.2, and a ratio of a distance between the fourth center and the third center to a distance between the fourth center and the first center is greater than 1 and equal to or less than 1.2.

In some embodiments, the minimum distance between the second pattern and the first pattern in the same first repeating unit is smaller than a minimum distance between the second pattern and a first pattern in an adjacent first repeating unit and adjacent to the second pattern in the first direction; and the minimum distance between the fourth pattern and the first pattern in the same first repeating unit is smaller than a minimum distance between the fourth pattern and a first pattern in an adjacent first repeating unit and adjacent to the fourth pattern in the second direction.

In some embodiments, a ratio of a distance between the second center and a first center in an adjacent first repeating unit and adjacent to the second center in the first direction to the distance between the second center and the first center in the same first repeating unit is greater than 1 and equal to or less than 1.2, and a ratio of a distance between the fourth center and a first center in an adjacent first repeating unit and adjacent to the fourth center in the second direction to the distance between the fourth center and the first center in the same first repeating unit is greater than 1 and equal to or less than 1.2.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the eleventh cathode selection pattern on the base substrate is between the sixth pattern in the corresponding first repeating unit and a seventh pattern adjacent to the sixth pattern in the second direction and in an adjacent first repeating unit; the orthographic projection of the twelfth cathode selection pattern on the base substrate is between the fifth pattern in the corresponding first repeating unit and the sixth pattern in the corresponding first repeating unit; the orthographic projection of the thirteenth cathode selection pattern on the base substrate is between the fifth pattern in the corresponding first repeating unit and the eighth pattern in the corresponding first repeating unit; and the orthographic projection of the fourteenth cathode selection pattern on the base substrate is between the eighth pattern in the corresponding first repeating unit and a seventh pattern adjacent to the eighth pattern in the first direction and in an adjacent first repeating unit.

In some embodiments, at least one first repeating unit is configured with at least one corresponding support pattern; the corresponding support patterns configured by each first repeating unit include: at least one of an eleventh support pattern, a twelfth support pattern, a thirteenth support pattern, and a fourteenth support pattern; an orthographic projection of the eleventh support pattern on the base substrate is between the first pattern in the corresponding first repeating unit and the second pattern in the corresponding first repeating unit; an orthographic projection of the twelfth support pattern on the base substrate is between the first pattern in the corresponding first repeating unit and the fourth pattern in the corresponding first repeating unit; an orthographic projection of the thirteenth support pattern on the base substrate is between the third pattern in the corresponding first repeating unit and a fourth pattern adjacent to the third pattern in the first direction and in an adjacent first repeating unit; and an orthographic projection of the fourteenth support pattern on the base substrate is between the third pattern in the corresponding first repeating unit and a second pattern adjacent to the third pattern in the second direction and in an adjacent first repeating unit.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the eleventh support pattern on the base substrate is between the fifth pattern in the corresponding first repeating unit and an eighth pattern adjacent to the fifth pattern in the second direction and in an adjacent first repeating unit; the orthographic projection of the twelfth support pattern on the base substrate is between the fifth pattern in the corresponding first repeating unit and a sixth pattern adjacent to the fifth pattern in the first direction and in an adjacent first repeating unit; the orthographic projection of the thirteenth support pattern on the base substrate is between the sixth pattern in the corresponding first repeating unit and the seventh pattern in the corresponding first repeating unit; and the orthographic projection of the fourteenth support pattern on the base substrate is between the seventh pattern in the corresponding first repeating unit and the eighth pattern in the corresponding first repeating unit.

In some embodiments, in each first repeating unit, a minimum distance between the second pattern and the first pattern is greater than a minimum distance between the second pattern and the third pattern; a minimum distance between the fourth pattern and the first pattern is greater than a minimum distance between the fourth pattern and the third pattern; the corresponding cathode selection patterns configured by each first repeating unit include: at least one of an eleventh cathode selection pattern, a twelfth cathode selection pattern, a thirteenth cathode selection pattern, and a fourteenth cathode selection pattern; an orthographic projection of the eleventh cathode selection pattern on the base substrate is between the first pattern in the corresponding first repeating unit and the second pattern in the corresponding first repeating unit; an orthographic projection of the twelfth cathode selection pattern on the base substrate is between the first pattern in the corresponding first repeating unit and the fourth pattern in the corresponding first repeating unit; an orthographic projection of the thirteenth cathode selection pattern on the base substrate is between the third pattern in the corresponding first repeating unit and a fourth pattern adjacent to the third pattern in the first direction and in an adjacent first repeating unit; and an orthographic projection of the fourteenth cathode selection pattern on the base substrate is between the third pattern in the corresponding first repeating unit and a second pattern adjacent to the third pattern in the second direction and in an adjacent first repeating unit.

In some embodiments, in each first repeating unit, a ratio of a distance between the second center and the first center to a distance between the second center and the third center is greater than 1 and less than or equal to 1.2, and a ratio of a distance between the fourth center and the first center to a distance between the fourth center and the third center is greater than 1 and equal to or less than 1.2.

In some embodiments, the minimum distance between the third pattern and the second pattern in the same first repeating unit is smaller than a minimum distance between the third pattern and a second pattern in an adjacent first repeating unit and adjacent to the third pattern in the second direction; and the minimum distance between the third pattern and the fourth pattern in the same first repeating unit is smaller than a minimum distance between the third pattern and a fourth pattern in an adjacent first repeating unit and adjacent to the third pattern in the first direction.

In some embodiments, a ratio of a distance between the third center and a second center in an adjacent first repeating unit and adjacent to the third center in the second direction to the distance between the third center and the second center in the same first repeating unit is greater than 1 and equal to or less than 1.2, and a ratio of a distance between the third center and a fourth center in an adjacent first repeating unit and adjacent to the third center in the first direction to the distance between the third center and the fourth center in the same first repeating unit is greater than 1 and equal to or less than 1.2.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the eleventh cathode selection pattern on the base substrate is between the fifth pattern in the corresponding first repeating unit and an eighth pattern adjacent to the fifth pattern in the second direction and in an adjacent first repeating unit; the orthographic projection of the twelfth cathode selection pattern on the base substrate is between the fifth pattern in the corresponding first repeating unit and a sixth pattern adjacent to the fifth pattern in the first direction and in an adjacent first repeating unit; the orthographic projection of the thirteenth cathode selection pattern on the base substrate is between the sixth pattern in the corresponding first repeating unit and the seventh pattern in the corresponding first repeating unit; and the orthographic projection of the fourteenth cathode selection pattern on the base substrate is between the seventh pattern in the corresponding first repeating unit and the eighth pattern in the corresponding first repeating unit.

In some embodiments, at least one first repeating unit is configured with at least one corresponding support pattern; the corresponding support patterns configured by each first repeating unit include: at least one of an eleventh support pattern, a twelfth support pattern, a thirteenth support pattern, and a fourteenth support pattern; an orthographic projection of the eleventh support pattern on the base substrate is between the second pattern in the corresponding first repeating unit and a first pattern adjacent to the second pattern in the first direction and in an adjacent first repeating unit; an orthographic projection of the twelfth support pattern on the base substrate is between the second pattern in the corresponding first repeating unit and the third pattern in the corresponding first repeating unit; an orthographic projection of the thirteenth support pattern on the base substrate is between the third pattern in the corresponding first repeating unit and the fourth pattern in the corresponding first repeating unit; and an orthographic projection of the fourteenth support pattern on the base substrate is between the fourth pattern in the corresponding first repeating unit and a first pattern adjacent to the fourth pattern in the second direction and in an adjacent first repeating unit.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the eleventh support pattern on the base substrate is between the sixth pattern in the corresponding first repeating unit and a seventh pattern adjacent to the sixth pattern in the second direction and in an adjacent first repeating unit; the orthographic projection of the twelfth support pattern on the base substrate is between the fifth pattern in the corresponding first repeating unit and the sixth pattern in the corresponding first repeating unit; the orthographic projection of the thirteenth support pattern on the base substrate is between the fifth pattern in the corresponding first repeating unit and the eighth pattern in the corresponding first repeating unit; and the orthographic projection of the fourteenth support pattern on the base substrate is between the eighth pattern in the corresponding first repeating unit and a seventh pattern adjacent to the eighth pattern in the first direction and in an adjacent first repeating unit.

In some embodiments, in each first repeating unit, a minimum distance between the first pattern and the second pattern is greater than a minimum distance between the first pattern and the fourth pattern; a minimum distance between the third pattern and the second pattern is greater than a minimum distance between the third pattern and the fourth pattern; the corresponding cathode selection patterns configured by each first repeating unit include: at least one of an eleventh cathode selection pattern, a twelfth cathode selection pattern, a thirteenth cathode selection pattern, and a fourteenth cathode selection pattern; an orthographic projection of the eleventh cathode selection pattern on the base substrate is between the first pattern in the corresponding first repeating unit and the second pattern in the corresponding first repeating unit; an orthographic projection of the twelfth cathode selection pattern on the base substrate is between the second pattern in the corresponding first repeating unit and the third pattern in the corresponding first repeating unit; an orthographic projection of the thirteenth cathode selection pattern on the base substrate is between the third pattern in the corresponding first repeating unit and a fourth pattern adjacent to the third pattern in the first direction and in an adjacent first repeating unit; and an orthographic projection of the fourteenth cathode selection pattern on the base substrate is between the fourth pattern in the corresponding first repeating unit and a first pattern adjacent to the fourth pattern in the second direction and in an adjacent first repeating unit.

In some embodiments, in each first repeating unit, a ratio of a distance between the first center and the second center to a distance between the first center and the fourth center is greater than 1 and less than or equal to 1.2, and a ratio of a distance between the third center and the second center to a distance between the third center and the fourth center is greater than 1 and equal to or less than 1.2.

In some embodiments, the minimum distance between the fourth pattern and the first pattern in the same first repeating unit is smaller than a minimum distance between the fourth pattern and a first pattern in an adjacent first repeating unit and adjacent to the fourth pattern in the second direction; and the minimum distance between the fourth pattern and the third pattern in the same first repeating unit is smaller than a minimum distance between the fourth pattern and a third pattern in an adjacent first repeating unit and adjacent to the fourth pattern in the first direction.

In some embodiments, a ratio of a distance between the fourth center and a first center in an adjacent first repeating unit and adjacent to the fourth center in the second direction to the distance between the fourth center and the first center in the same first repeating unit is greater than 1 and equal to or less than 1.2, and a ratio of a distance between the fourth center and a third center in an adjacent first repeating unit and adjacent to the fourth center in the first direction to the distance between the third center and the fourth center in the same first repeating unit is greater than 1 and equal to or less than 1.2.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the eleventh cathode selection pattern on the base substrate is between the fifth pattern in the corresponding first repeating unit and an eighth pattern adjacent to the fifth pattern in the second direction and in an adjacent first repeating unit; the orthographic projection of the twelfth cathode selection pattern on the base substrate is between the fifth pattern in the corresponding first repeating unit and the sixth pattern in the corresponding first repeating unit; the orthographic projection of the thirteenth cathode selection pattern on the base substrate is between the sixth pattern in the corresponding first repeating unit and the seventh pattern in the corresponding first repeating unit; and the orthographic projection of the fourteenth cathode selection pattern on the base substrate is between the eighth pattern in the corresponding first repeating unit and a seventh pattern adjacent to the eighth pattern in the first direction and in an adjacent first repeating unit.

In some embodiments, at least one first repeating unit is configured with at least one corresponding support pattern; the corresponding support patterns configured by each first repeating unit include: at least one of an eleventh support pattern, a twelfth support pattern, a thirteenth support pattern, and a fourteenth support pattern; an orthographic projection of the eleventh support pattern on the base substrate is between the second pattern in the corresponding first repeating unit and a first pattern adjacent to the second pattern in the first direction and in an adjacent first repeating unit; an orthographic projection of the twelfth support pattern on the base substrate is between the first pattern in the corresponding first repeating unit and the fourth pattern in the corresponding first repeating unit; an orthographic projection of the thirteenth support pattern on the base substrate is between the third pattern in the corresponding first repeating unit and the fourth pattern in the corresponding first repeating unit; and an orthographic projection of the fourteenth support pattern on the base substrate is between the third pattern in the corresponding first repeating unit and a second pattern adjacent to the third pattern in the second direction and in an adjacent first repeating unit.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the eleventh support pattern on the base substrate is between the sixth pattern in the corresponding first repeating unit and a seventh pattern adjacent to the sixth pattern in the second direction and in an adjacent first repeating unit; the orthographic projection of the twelfth support pattern on the base substrate is between the fifth pattern in the corresponding first repeating unit and a sixth pattern adjacent to the fifth pattern in the first direction and in an adjacent first repeating unit; the orthographic projection of the thirteenth support pattern on the base substrate is between the fifth pattern in the corresponding first repeating unit and the eighth pattern in the corresponding first repeating unit; and the orthographic projection of the fourteenth support pattern on the base substrate is between the seventh pattern in the corresponding first repeating unit and the eighth pattern in the corresponding first repeating unit.

In some embodiments, in each first repeating unit, a minimum distance between the first pattern and the fourth pattern is greater than a minimum distance between the first pattern and the second pattern; a minimum distance between the third pattern and the fourth pattern is greater than a minimum distance between the third pattern and the second pattern; the corresponding cathode selection patterns configured by each first repeating unit include: at least one of an eleventh cathode selection pattern, a twelfth cathode selection pattern, a thirteenth cathode selection pattern, and a fourteenth cathode selection pattern; an orthographic projection of the eleventh cathode selection pattern on the base substrate is between the second pattern in the corresponding first repeating unit and a first pattern adjacent to the second pattern in the first direction and in an adjacent first repeating unit; an orthographic projection of the twelfth cathode selection pattern on the base substrate is between the first pattern in the corresponding first repeating unit and the fourth pattern in the corresponding first repeating unit; an orthographic projection of the thirteenth cathode selection pattern on the base substrate is between the third pattern in the corresponding first repeating unit and the fourth pattern in the corresponding first repeating unit; and an orthographic projection of the fourteenth cathode selection pattern on the base substrate is between the third pattern in the corresponding first repeating unit and a second pattern adjacent to the third pattern in the second direction and in an adjacent first repeating unit.

In some embodiments, in each first repeating unit, a ratio of a distance between the first center and the fourth center to a distance between the first center and the second center is greater than 1 and less than or equal to 1.2, and a ratio of a distance between the third center and the fourth center to a distance between the third center and the second center is greater than 1 and less than or equal to 1.2.

In some embodiments, the minimum distance between the second pattern and the first pattern in the same first repeating unit is smaller than a minimum distance between the second pattern and a first pattern in an adjacent first repeating unit and adjacent to the second pattern in the first direction; and the minimum distance between the third pattern and the second pattern in the same first repeating unit is smaller than a minimum distance between the third pattern and a second pattern in an adjacent first repeating unit and adjacent to the third pattern in the second direction.

In some embodiments, a ratio of a distance between the second center and a first center in an adjacent first repeating unit and adjacent to the second center in the second direction to the distance between the second center and the first center in the same first repeating unit is greater than 1 and equal to or less than 1.2, and a ratio of a distance between the third center and a second center in an adjacent first repeating unit and adjacent to the third center in the first direction to the distance between the third center and the second center in the same first repeating unit is greater than 1 and equal to or less than 1.2.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the eleventh cathode selection pattern on the base substrate is between the sixth pattern in the corresponding first repeating unit and a seventh pattern adjacent to the sixth pattern in the second direction and in an adjacent first repeating unit; the orthographic projection of the twelfth cathode selection pattern on the base substrate is between the fifth pattern in the corresponding first repeating unit and a sixth pattern adjacent to the fifth pattern in the first direction and in an adjacent first repeating unit; the orthographic projection of the thirteenth cathode selection pattern on the base substrate is between the fifth pattern in the corresponding first repeating unit and the eighth pattern in the corresponding first repeating unit; and the orthographic projection of the fourteenth cathode selection pattern on the base substrate is between the seventh pattern in the corresponding first repeating unit and the eighth pattern in the corresponding first repeating unit.

In some embodiments, at least one first repeating unit is configured with at least one corresponding support pattern; the corresponding support patterns configured by each first repeating unit include: at least one of an eleventh support pattern, a twelfth support pattern, a thirteenth support pattern, and a fourteenth support pattern; an orthographic projection of the eleventh support pattern on the base substrate is between the first pattern in the corresponding first repeating unit and the second pattern in the corresponding first repeating unit; an orthographic projection of the twelfth support pattern on the base substrate is between the second pattern in the corresponding first repeating unit and the third pattern in the corresponding first repeating unit; an orthographic projection of the thirteenth support pattern on the base substrate is between the third pattern in the corresponding first repeating unit and a fourth pattern adjacent to the third pattern in the first direction and in an adjacent first repeating unit; and an orthographic projection of the fourteenth support pattern on the base substrate is between the fourth pattern in the corresponding first repeating unit and a first pattern adjacent to the fourth pattern in the second direction and in an adjacent first repeating unit.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the eleventh support pattern on the base substrate is between the fifth pattern in the corresponding first repeating unit and an eighth pattern adjacent to the fifth pattern in the second direction and in an adjacent first repeating unit; the orthographic projection of the twelfth support pattern on the base substrate is between the fifth pattern in the corresponding first repeating unit and the sixth pattern in the corresponding first repeating unit; the orthographic projection of the thirteenth support pattern on the base substrate is between the sixth pattern in the corresponding first repeating unit and the seventh pattern in the corresponding first repeating unit; and the orthographic projection of the fourteenth support pattern on the base substrate is between the eighth pattern in the corresponding first repeating unit and a seventh pattern adjacent to the eighth pattern in the first direction and in an adjacent first repeating unit.

In some embodiments, in each first repeating unit, a minimum distance between the first pattern and the second pattern is greater than a minimum distance between the second pattern and the third pattern; a minimum distance between the first pattern and the fourth pattern is greater than the minimum distance between the second pattern and the third pattern; a minimum distance between the fourth pattern and the third pattern is greater than the minimum distance between the second pattern and the third pattern; the corresponding cathode selection patterns configured by each first repeating unit include: at least one of a twenty-first cathode selection pattern, a twenty-second cathode selection pattern, a twenty-third cathode selection pattern, and a twenty-fourth cathode selection pattern; an orthographic projection of the twenty-first cathode selection pattern on the base substrate is between the first pattern in the corresponding first repeating unit and the second pattern in the corresponding first repeating unit; an orthographic projection of the twenty-second cathode selection pattern on the base substrate is between the first pattern in the corresponding first repeating unit and the fourth pattern in the corresponding first repeating unit; an orthographic projection of the twenty-third cathode selection pattern on the base substrate is between the third pattern in the corresponding first repeating unit and the fourth pattern in the corresponding first repeating unit; and an orthographic projection of the twenty-fourth cathode selection pattern on the base substrate is between the third pattern in the corresponding first repeating unit and a second pattern adjacent to the third pattern in the second direction and in an adjacent first repeating unit.

In some embodiments, in each first repeating unit, a ratio of a distance between the first center and the second center to a distance between the second center and the third center is greater than 1 and less than or equal to 1.2, a ratio of a distance between the first center and the fourth center to the distance between the second center and the third center is greater than 1 and equal to or less than 1.2, and a ratio of a distance between the fourth center and the third center to the distance between the second center and the third center is greater than 1 and equal to or less than 1.2.

In some embodiments, the minimum distance between the second pattern and the third pattern in the same first repeating unit is smaller than a minimum distance between the second pattern and a third pattern in an adjacent first repeating unit and adjacent to the second pattern in the second direction.

In some embodiments, a ratio of a distance between the second center and a third center in an adjacent first repeating unit and adjacent to the second center in the second direction to the distance between the second center and the third center in the same first repeating unit is greater than 1 and equal to or less than 1.2.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the twenty-first cathode selection pattern on the base substrate is between the fifth pattern in the corresponding first repeating unit and an eighth pattern adjacent to the fifth pattern in the second direction and in an adjacent first repeating unit; the orthographic projection of the twenty-second cathode selection pattern on the base substrate is between the fifth pattern in the corresponding first repeating unit and a sixth pattern adjacent to the fifth pattern in the first direction and in an adjacent first repeating unit; the orthographic projection of the twenty-third cathode selection pattern on the base substrate is between the fifth pattern in the corresponding first repeating unit and the eighth pattern in the corresponding first repeating unit; and the orthographic projection of the twenty-fourth cathode selection pattern on the base substrate is between the seventh pattern in the corresponding first repeating unit and the eighth pattern in the corresponding first repeating unit.

In some embodiments, at least one first repeating unit is configured with at least one corresponding support pattern; the corresponding support patterns configured by each first repeating unit include: at least one of a twenty-first support pattern, and a twenty-second support pattern; an orthographic projection of the twenty-first support pattern on the base substrate is between the second pattern in the corresponding first repeating unit and the third pattern in the corresponding first repeating unit; and an orthographic projection of the twenty-second support pattern on the base substrate is between the third pattern in the corresponding first repeating unit and a fourth pattern adjacent to the third pattern in the first direction and in an adjacent first repeating unit.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the twenty-first support pattern on the base substrate is between the fifth pattern in the corresponding first repeating unit and the sixth pattern in the corresponding first repeating unit; and the orthographic projection of the twenty-second support pattern on the base substrate is between the sixth pattern in the corresponding first repeating unit and the seventh pattern in the corresponding first repeating unit.

In some embodiments, in each first repeating unit, a minimum distance between the first pattern and the second pattern is greater than a minimum distance between the first pattern and a second pattern in an adjacent first repeating unit and adjacent to the first pattern in the first direction; a minimum distance between the first pattern and the fourth pattern is greater than a minimum distance between the first pattern and a fourth pattern in an adjacent first repeating unit and adjacent to the first pattern in the second direction; a minimum distance between the fourth pattern and the third pattern is greater than a minimum distance between the fourth pattern and a third pattern in an adjacent first repeating unit and adjacent to the fourth pattern in the first direction; a minimum distance between the third pattern and the second pattern is greater than a minimum distance between the third pattern and a second pattern in an adjacent first repeating unit and adjacent to the third pattern in the second direction; the corresponding cathode selection patterns configured by each first repeating unit include: at least one of a thirty-first cathode selection pattern, a thirty-second cathode selection pattern, a thirty-third cathode selection pattern, and a thirty-fourth cathode selection pattern; an orthographic projection of the thirty-first cathode selection pattern on the base substrate is between the first pattern in the corresponding first repeating unit and the second pattern in the corresponding first repeating unit; an orthographic projection of the thirty-second cathode selection pattern on the base substrate is between the first pattern in the corresponding first repeating unit and the fourth pattern in the corresponding first repeating unit; an orthographic projection of the thirty-third cathode selection pattern on the base substrate is between the third pattern in the corresponding first repeating unit and the fourth pattern in the corresponding first repeating unit; and an orthographic projection of the thirty-fourth cathode selection pattern on the base substrate is between the second pattern in the corresponding first repeating unit and the third pattern in the corresponding first repeating unit.

In some embodiments, in each first repeating unit, a ratio of a distance between the first center and the second center to a distance between the first center and a second center in an adjacent first repeating unit and adjacent to the first center in the first direction is greater than 1 and equal to or less than 1.2; a ratio of a distance between the first center and the fourth center to a distance between the first center and a fourth center in an adjacent first repeating unit and adjacent to the first center in the second direction is greater than 1 and equal to or less than 1.2; a ratio of a distance between the fourth center and the third center to a distance between the fourth center and a third center in an adjacent first repeating unit and adjacent to the fourth center in the first direction is greater than 1 and equal to or less than 1.2; and a ratio of a distance between the third center and the second center to a distance between the third center and a second center in an adjacent first repeating unit and adjacent to the third center in the second direction is greater than 1 and equal to or less than 1.2.

In some embodiments, four sides of the first quadrangle are all equal in length.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the thirty-first cathode selection pattern on the base substrate is between the fifth pattern in the corresponding first repeating unit and an eighth pattern adjacent to the fifth pattern in the second direction and in an adjacent first repeating unit; the orthographic projection of the thirty-second cathode selection pattern on the base substrate is between the fifth pattern in the corresponding first repeating unit and a sixth pattern adjacent to the fifth pattern in the first direction and in an adjacent first repeating unit; the orthographic projection of the thirty-third cathode selection pattern on the base substrate is between the fifth pattern in the corresponding first repeating unit and the eighth pattern in the corresponding first repeating unit; and the orthographic projection of the thirty-fourth cathode selection pattern on the base substrate is between the fifth pattern in the corresponding first repeating unit and the sixth pattern in the corresponding first repeating unit.

In some embodiments, at least one first repeating unit is configured with at least one corresponding support pattern; the corresponding support patterns configured by each first repeating unit include: at least one of a thirty-first support pattern, and a thirty-second support pattern; an orthographic projection of the thirty-first support pattern on the base substrate is between the third pattern in the corresponding first repeating unit and a fourth pattern adjacent to the third pattern in the first direction and in an adjacent first repeating unit; and an orthographic projection of the thirty-second support pattern on the base substrate is between the third pattern in the corresponding first repeating unit and a second pattern adjacent to the third pattern in the second direction and in an adjacent first repeating unit.

In some embodiments, the first repeating unit further includes: four third sub-pixels, and a pixel opening corresponding to each third sub-pixel is a third pixel opening; patterns of orthographic projections of the four third pixel openings on the base substrate are a fifth pattern, a sixth pattern, a seventh pattern and an eighth pattern, respectively, the fifth pattern is inside a region defined by the first quadrangle, and the sixth pattern, the seventh pattern and the eighth pattern are outside the region defined by the first quadrangle; the orthographic projection of the thirty-first support pattern on the base substrate is between the sixth pattern in the corresponding first repeating unit and the seventh pattern in the corresponding first repeating unit; and the orthographic projection of the thirty-second support pattern on the base substrate is between the seventh pattern in the corresponding first repeating unit and the eighth pattern in the corresponding first repeating unit.

In some embodiments, a line connecting the first center of the first pattern and the third center of the third pattern in each first repeating unit extends along a third direction; four centers, including the center of the third pattern in the first repeating unit, a center of a second pattern adjacent to the third pattern in the second direction and in an adjacent first repeating unit, a center of a first pattern adjacent to the third pattern in the third direction and in an adjacent first repeating unit, and a center of a fourth pattern adjacent to the third pattern in the first direction and in an adjacent first repeating unit, are sequentially connected to form a third quadrangle corresponding to the first repeating unit; the corresponding cathode selection patterns configured by the first repeating unit include: at least one of a forty-first cathode selection pattern and a forty-second cathode selection pattern; an orthographic projection of the forty-first cathode selection pattern on the base substrate is in a region surrounded by the first quadrangle corresponding to the first repeating unit and covers a center of the first quadrangle; and an orthographic projection of the forty-second cathode selection pattern on the base substrate is in a region surrounded by the third quadrangle corresponding to the first repeating unit and covers a center of the third quadrangle.

In some embodiments, each first repeating unit further includes two third sub-pixels, and a pixel opening corresponding to each third sub-pixel is a third pixel opening, and orthographic projections of the two third pixel openings on the base substrate are a sixth pattern and an eighth pattern, respectively, the sixth pattern and the first quadrangle corresponding to the same first repeating unit are arranged along the second direction, and the eighth pattern and the first quadrangle corresponding to the same first repeating unit are arranged along the first direction.

In some embodiments, a line connecting the second center of the second pattern and the fourth center of the fourth pattern in the same first repeating unit extends along a fourth direction; at least one first repeating unit is configured with at least one corresponding support pattern; the corresponding support patterns configured by the first repeating unit include: at least one of a forty-first support pattern, a forty-second support pattern, a forty-third support pattern, and a forty-fourth support pattern; an orthographic projection of the forty-fourth support pattern on the base substrate is between the sixth pattern in the corresponding first repeating unit and a first pattern adjacent to the sixth pattern in the fourth direction and in an adjacent first repeating unit; an orthographic projection of the forty-second support pattern on the base substrate is between the sixth pattern in the corresponding first repeating unit and the third pattern in the corresponding first repeating unit; an orthographic projection of the forty-third support pattern on the base substrate is between the eighth pattern in the corresponding first repeating unit and the third pattern in the corresponding first repeating unit; and an orthographic projection of the forty-fourth support pattern on the base substrate is between the eighth pattern in the corresponding first repeating unit and a first pattern adjacent to the eighth pattern in the fourth direction and in an adjacent first repeating unit.

In some embodiments, a length of the forty-first cathode selection pattern in the first direction is greater than a minimum distance between the first pattern and the second pattern in the corresponding first repeating unit in the first direction; a length of the forty-first cathode selection pattern in the second direction is greater than a minimum distance between the first pattern and the fourth pattern in the corresponding first repeating unit in the second direction; a length of the forty-second cathode selection pattern in the first direction is greater than the minimum distance between the first pattern and the second pattern in the corresponding first repeating unit in the first direction; and a length of the forty-second cathode selection pattern in the second direction is greater than the minimum distance between the first pattern and the fourth pattern in the corresponding first repeating unit in the second direction.

In some embodiments, the cathode layer includes: a plurality of cathode selection patterns in one-to-one correspondence with the plurality of pixel openings, and an orthographic projection of each cathode selection pattern on the base substrate covers an orthographic projection of the corresponding pixel opening on the base substrate; and the cathode layer further includes a plurality of cathode lines sequentially arranged along the second direction, and the plurality of cathode selection patterns are connected to the corresponding cathode lines.

In some embodiments, the display substrate includes a first display region and a plurality of sub-pixel groups in the first display region and sequentially arranged along the second direction, and the plurality of sub-pixel groups include: one first sub-pixel sub-group and one second sub-pixel sub-group arranged in the second direction; the first sub-pixel sub-group includes first sub-pixels and second sub-pixels alternately arranged in the first direction, the second sub-pixel sub-group includes a plurality of third sub-pixels sequentially arranged in the first direction, and the plurality of third sub-pixels are arranged in a staggering way with the first sub-pixels and the second sub-pixels in the first direction; and the plurality of sub-pixel groups are in one-to-one correspondence with the plurality of cathode lines, and each cathode line is between the first sub-pixel sub-group and the second sub-pixel sub-group in the corresponding sub-pixel group, and is connected to the cathode selection patterns corresponding to the first sub-pixels, the second sub-pixels and the plurality of third sub-pixels in the corresponding sub-pixel group.

In some embodiments, the plurality of support patterns are in the first display region, and an orthographic projection of each cathode line on the base substrate covers an orthographic projection of a corresponding support pattern on the base substrate.

In some embodiments, the pixel opening corresponding to each first sub-pixel is a first pixel opening, the pixel opening corresponding to each second sub-pixel is a second pixel opening, and the pixel opening corresponding to each third sub-pixel is a third pixel opening; in the first display region, a pattern of an orthographic projection of each first pixel opening on the base substrate is an eleventh pattern, a pattern of an orthographic projection of each second pixel opening on the base substrate is a twelfth pattern, and a pattern of an orthographic projection of each third pixel opening on the base substrate is a thirteenth pattern; a minimum distance between the thirteenth pattern and the eleventh pattern closest to each other in the same sub-pixel group is greater than a minimum distance between the thirteenth pattern and the twelfth pattern closest to each other in the same sub-pixel group; and an orthographic projection of each support pattern on the base substrate is between the thirteenth pattern and the eleventh pattern closest to each other in the same sub-pixel group and corresponding to the support pattern.

In some embodiments, each first sub-pixel is a sub-pixel for emitting red light, and each second sub-pixel is a sub-pixel for emitting blue light.

In some embodiments, the plurality of third sub-pixels are in the display substrate, and each third sub-pixel is a sub-pixel for emitting green light.

In some embodiments, the cathode layer is on a side of the plurality of support patterns away from the base substrate; or the plurality of support patterns are on a side of the cathode layer away from the base substrate.

In a second aspect, an embodiment of the present disclosure further provides a display apparatus, including: the display substrate as provided in the first aspect.

### BRIEF DESCRIPTION OF DRAWINGS

FIG. 1 is a schematic diagram of a structure of a display substrate according to an embodiment of the present disclosure;

FIG. 2 is a schematic cross-sectional view taken along a line A-A′ of FIG. 1;

FIG. 3 is a schematic cross-sectional view of a display substrate with a cathode selection pattern thereon according to an embodiment of the present disclosure;

FIGS. 4A and 4B are two different schematic top views of a portion of a display substrate according to an embodiment of the present disclosure;

FIG. 5 is another schematic top view of a portion of a display substrate according to an embodiment of the present disclosure;

FIG. 6 is a schematic top view of a local region in a first display region in the present disclosure;

FIG. 7A is a schematic top view of a local region in a first display region according to an embodiment of the present disclosure;

FIG. 7B is a schematic top view of a local region with a support pattern in FIG. 7A;

FIG. 8A is another schematic top view of a local region in a first display region according to an embodiment of the present disclosure;

FIG. 8B is a schematic top view of a local region with a support pattern in FIG. 8A;

FIG. 9A is another schematic top view of a local region in a first display region according to an embodiment of the present disclosure;

FIG. 9B is a schematic top view of a local region with a support pattern in FIG. 9A;

FIG. 10A is another schematic top view of a local region in a first display region according to an embodiment of the present disclosure;

FIG. 10B is a schematic top view of a local region with a support pattern in FIG. 10A;

FIG. 11A is another schematic top view of a local region in a first display region according to an embodiment of the present disclosure;

FIG. 11B is a schematic top view of a local region with a support pattern in FIG. 11A;

FIG. 12A is another schematic top view of a local region in a first display region according to an embodiment of the present disclosure;

FIG. 12B is a schematic top view of a local region with a support pattern in FIG. 12A;

FIG. 13A is another schematic top view of a local region in a first display region according to an embodiment of the present disclosure;

FIG. 13B is a schematic top view of a local region with a support pattern in FIG. 13A;

FIG. 14A is another schematic top view of a local region in a first display region according to an embodiment of the present disclosure;

FIG. 14B is a schematic top view of a local region with a support pattern in FIG. 14A;

FIG. 15A is another schematic top view of a local region in a first display region according to an embodiment of the present disclosure;

FIG. 15B is a schematic top view of a local region with a support pattern in FIG. 15A;

FIG. 16 is a schematic top view of a portion of a display substrate in the present disclosure; and

FIG. 17 is a schematic diagram of a display apparatus according to an embodiment of the present disclosure.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings. It is to be understood that the described embodiments are only a few, not all of, embodiments of the present disclosure. All other embodiments, which can be derived by a person skilled in the art from the embodiments of the present disclosure without any creative effort, are within the protective scope of the present disclosure.

It should be noted that in the drawings, a size and a relative size of elements may be exaggerated for clarity and/or description. As such, the size and the relative size of the respective elements are not necessarily limited to those shown in the drawings. In the description and drawings, the same or similar reference numerals denote the same or similar parts.

When an element is described to as being “on”, “connected to” or “coupled to” another element, the element may be directly on, connected or coupled to the another element or intervening elements may be therebetween. However, when an element is described to as being “directly on”, “directly connected to” or “directly coupled to” another element, there are no intervening elements therebetween. Other terms and/or expressions used to describe a relationship between elements should be interpreted in a similar manner, e.g., “between” corresponding to “directly between”, “adjacent” corresponding to “directly adjacent” or “on” corresponding to “directly on” or the like. Further, the term “connected” may refer to physical, electrical, communication, and/or fluid connections. Further, an X axis, a Y axis, and a Z axis are not limited to three axes of a rectangular coordinate system, and may be interpreted in a broader sense. For example, the X axis, the Y axis, and the Z axis may be perpendicular to each other, or may represent different directions not perpendicular to each other.

It will be understood that although the terms “first”, and “second” and the like may be used herein to describe various parts, components, elements, regions, layers and/or portions, these parts, components, elements, regions, layers and/or portions should not be limited by these terms. Rather, these terms are used to distinguish one part, one component, one element, one region, one layer and/or one portion from another. Thus, for example, a first part, a first component, a first element, a first region, a first layer and/or a first portion could be termed a second part, a second component, a second element, a second region, a second layer and/or a second portion without departing from the teachings of the present disclosure.

For convenience in description, spatial relationship terms, such as “upper”, “lower”, “left”, “right”, and the like, may be used herein to describe a relationship between one element or feature and another element or feature as illustrated in the drawings. It will be understood that the spatial relationship terms are intended to encompass different orientations of a device in use or operation in addition to an orientation depicted in the drawings. For example, if the device in the drawings is turned over, elements described as “below” or “beneath” other elements or features would then be oriented “above” or “over” the other elements or features.

Herein, the expression “repeating unit” may mean that at least two or more units are disposed in a display substrate and are repeatedly arranged in close proximity to each other. The repeating unit may represent a combination of a plurality of sub-pixels, for example, a combination of a plurality of sub-pixels for displaying one pixel, and a plurality of “repeating units” are repeatedly arranged in an array on the base substrate. For example, a repeating unit may include at least one pixel, and may specifically include two, three, four, or more sub-pixels. Further, herein, for convenience of description, a repeating unit located in a first display region is referred to as a first repeating unit, and a repeating unit located in a second display region is referred to as a second repeating unit.

Herein, the expression “pixel density” denotes the number of repeating units or sub-pixels per unit area. Similarly, the expression “distribution density” denotes the number of components (e.g., repeating units, sub-pixels, spacers or the like) per unit area.

Herein, unless otherwise specifically stated, the expression “pixel opening” means an opening in a pixel defining layer corresponding to a sub-pixel. A pixel opening exposes at least a portion of an anode of a light emitting device of the sub-pixel, and at least a portion of a light emitting layer of the light emitting device is also located in the pixel opening. That is, the pixel opening corresponds to a light emitting region of the sub-pixel.

In this context, the expression “center of pattern” means a geometric center or centroid of the pattern, unless otherwise specifically stated. For example, in the case where the pattern is a circle, the center of the pattern is a center of the circle. In the case where the pattern is an ellipse, the center of the pattern is a center of the ellipse, that is, an intersection point of a major axis and a minor axis of the ellipse. In the case where the pattern is a rectangle, the center of the pattern is a center of the rectangle, i.e., an intersection point of two diagonal lines of the rectangle.

As used herein, “light transmittance” refers to an ability of light to transmit through a medium and is a percentage of an amount of light transmitted through a transparent or translucent object with respect to an amount of light incident upon the transparent or translucent object.

Herein, unless otherwise specifically stated, the expression “an extending direction of a line connecting A and B is parallel to the first direction” includes the following cases: A and B are located on the same straight line extending parallel to the first direction; positions of A and B have an error in a direction perpendicular to the first direction, the error is in the range of −5 microns to +5 microns.

In this context, a minimum distance between patterns M and N means a distance between a point of an edge of the pattern M closest to an edge of the pattern N and a point of the edge of the pattern N closest to the edge of the pattern M.

In the related art, the display panel may generally include: an anode layer, a light-emitting layer, and a cathode layer, which are stacked. The cathode layer is generally disposed in a whole layer in the display panel, and may be generally made of a transparent conductive material, such as a magnesium silver material.

However, the cathode layer made of a transparent conductive material has a low light transmittance. For example, the cathode layer having a thickness of 15 nanometers (nm) has a transmittance of only about 50% for light having a wavelength of 550 nm, and a transmittance of only about 30% for light having a wavelength of 940 nm. Therefore, the cathode layer disposed in a whole layer limits the light transmittance of the display substrate to some extent.

In order to effectively solve at least one technical problem in the prior art, embodiments of the present disclosure provide a display substrate and a display apparatus.

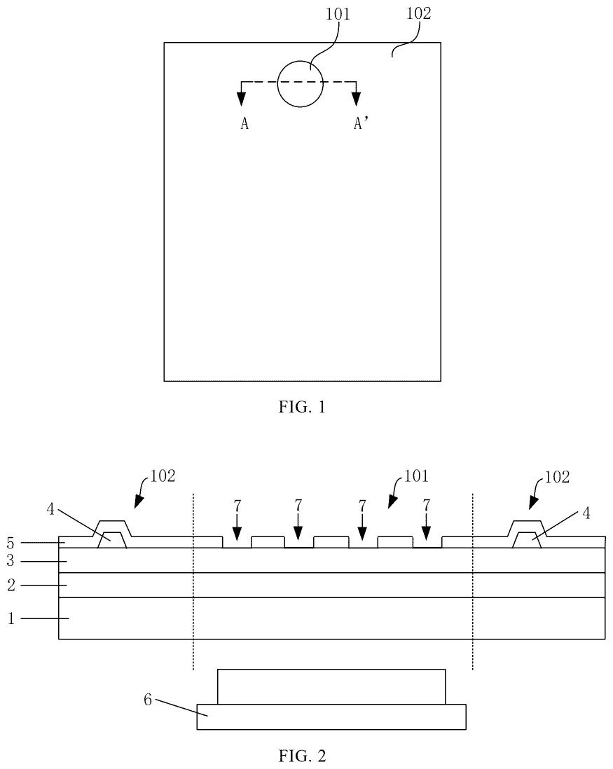

FIG. 1 is a schematic diagram of a structure of a display substrate according to an embodiment of the present disclosure; FIG. 2 is a schematic cross-sectional view taken along a line A-A′ of FIG. 1. As shown in FIGS. 1 and 2, an embodiment of the present disclosure provides a display substrate, including: a base substrate 1, a pixel defining layer 3, a plurality of support patterns 4 and a cathode layer 5. The pixel defining layer 3 is located on a side of the base substrate 1, and has a plurality of pixel openings 3a (not shown in FIG. 2). The plurality of support patterns 4 are located on a side of the pixel defining layer 3 away from the base substrate 1, the cathode layer 5 is located on a side of the pixel defining layer 3 away from the base substrate 1, and has a plurality of hollowed-out structures 7, and an orthographic projection of the hollowed-out structures 7 on the base substrate 1 does not overlap with an orthographic projection of the pixel openings 3a on the base substrate 1. With such a design, the light transmittance of at least partial region of the display substrate can be improved.

In some embodiments, the orthographic projection of the hollowed-out structures 7 on the base substrate 1 does not overlap with an orthographic projection of the support patterns 4 on the base substrate 1.

In the embodiment of the present disclosure, the cathode layer 5 may be located on a side of the support patterns 4 away from the base substrate 1, or the support patterns 4 may be located on a side of the cathode layer 5 away from the base substrate 1. Such two cases belong to the protection scope of the present disclosure. In the following embodiments, as an example, the cathode layer 5 is located on the side of the support patterns 4 away from the base substrate 1.

The support patterns 4 in the embodiment of the present disclosure may be used to support a fine metal mask (FMM) for evaporating a light emitting layer 9. In addition, when it is necessary to provide a cathode selection patterning material (CPM, hereinafter also referred to as a “cathode selection pattern”) on the display substrate, the support patterns 4 may be used to support an FMM for evaporating the cathode selection patterning material. By providing the support patterns 4, the FMMs used in the evaporating process can be effectively supported, and it can ensure that there is a small interval between the FMMs and the display substrate, thereby improving the precision of the patterns formed by the evaporating process.

In practical applications, a driving functional layer 2 is further provided between the base substrate 1 and the pixel defining layer 3, and a plurality of pixel driving circuits arranged in an array are provided in the driving functional layer 2, and are electrically connected to corresponding light emitting units for driving the corresponding light emitting units to emit light. Each pixel driving circuit may include a plurality of transistors and at least one capacitor. For example, each pixel driving circuit may have a 3T1C, 4T1C, 5T1C, 5T2C, 6T1C, 7T1C, or 8T1C structure. “T” in the above circuit structure refers to a thin film transistor, “C” refers to a capacitor, a number before T represents the number of thin film transistors in the circuit, and a number before C represents the number of capacitors in the circuit. In some embodiments, the plurality of transistors in the pixel circuit may be P-type transistors or N-type transistors. The transistors of the same type are adopted in the pixel circuit, so that the process flow can be simplified, the process difficulty for the display substrate is reduced, and the yield of products is improved. In other embodiments, the plurality of transistors in the pixel circuit may include the P-type transistors and the N-type transistors.

In some embodiments, the plurality of transistors in the pixel circuit may employ a low temperature poly-silicon thin film transistor, or an oxide thin film transistor, or a combination of them. An active layer of the low temperature poly-silicon thin film transistor adopts low temperature poly-silicon (LTPS), and an active layer of the oxide thin film transistor adopts oxide semiconductor (Oxide). The low temperature poly-silicon thin film transistor has the advantages of high mobility, high charging speed and the like, and the oxide thin film transistor has the advantages of low leakage current and the like. The low temperature poly-silicon thin film transistor and the oxide thin film transistor are integrated on one display substrate, that is, an LTPS+Oxide (i.e., LTPO) display substrate, so that the low-frequency driving can be realized, the power consumption can be reduced, and the display quality can be improved by utilizing the advantages of the low temperature poly-silicon thin film transistor and the oxide thin film transistor.

In some embodiments, a light emitting unit may be an organic light emitting diode (OLED), and emits red light, green light, blue light, white light, or the like under the driving of its corresponding pixel circuit. A light emitting color of the light emitting unit may be determined as desired. The light emitting unit may include: an anode, a cathode, and an organic light emitting structure disposed between the anode and the cathode, wherein the organic light emitting structure at least includes an organic light emitting layer 9, and may further include: at least one of a hole injection layer, a hole transport layer, an electron injection layer, and an electron transport layer. The anode of the light emitting unit may be electrically connected to the corresponding pixel circuit.

In addition, in the present disclosure, a shape of an orthographic projection of each pixel opening 3a on the base substrate 1 may be a circle, a rectangle, a pentagon, a hexagon or other regular or irregular shapes. In the following drawings, as an example, the shape of the orthographic projection of each pixel opening 3a on the base substrate 1 is a circle.

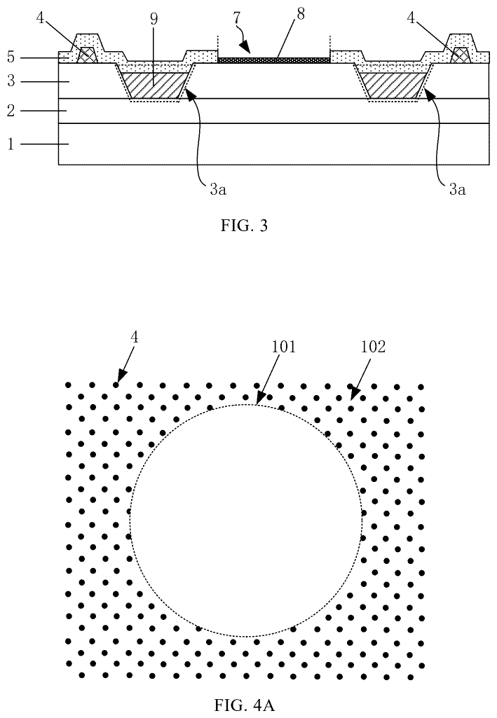

FIG. 3 is a schematic cross-sectional view of a display substrate with a cathode selection pattern thereon according to an embodiment of the present disclosure. As shown in FIG. 3, in some embodiments, the display substrate further includes a plurality of cathode selection patterns 8 in one-to-one correspondence with the hollowed-out structures 7, and an orthographic projection of each cathode selection pattern 8 on the base substrate 1 at least partially overlaps with an orthographic projection of the corresponding hollowed-out structure 7 on the base substrate 1.

In the embodiment of the present disclosure, the patterned CPM may be formed before forming the cathode layer 5, where the CPM is a material only for selectively depositing a cathode material. The cathode material is difficult to attach to a region where the CPM is formed during the process of forming the cathode layer 5 by a deposition process, so that an attachment area of the cathode layer 5 may be reduced to improve the light transmittance.

Generally, a region where the pixel opening 3a is located is a light emitting region of a sub-pixel. In order to ensure normal light emission of the sub-pixels, it is necessary to ensure that the patterned cathode layer 5 may completely cover each pixel opening 3a, and therefore the CPM is often designed at an interval between adjacent pixel openings 3a. The specific position for the CPM may be designed and adjusted in advance according to actual needs.

In some embodiments, an area of the orthographic projection of each cathode selection pattern 8 on the base substrate 1 is greater than an area of an orthographic projection of each support pattern 4 on the base substrate 1. That is, in the present disclosure, a size of each cathode selection pattern 8 may be larger than a size of each support pattern 4. With such a design, the layout of the support patterns 4 and the cathode selection patterns 8 are easily designed while ensuring effective improvement of the light transmittance, which will be described in detail below with reference to some examples.

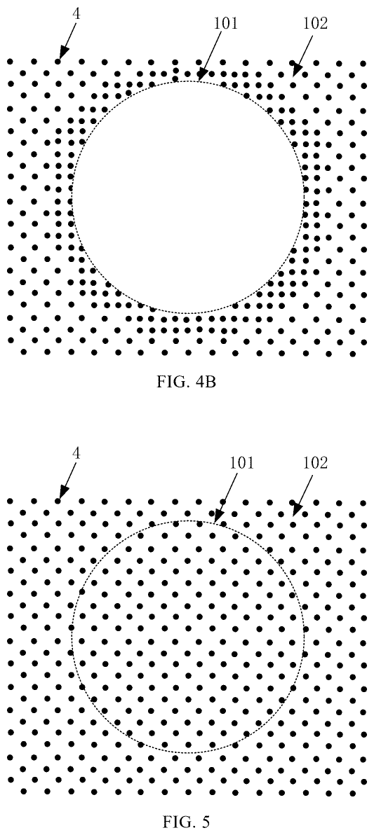

FIGS. 4A and 4B are two different schematic top views of a portion of a display substrate according to an embodiment of the present disclosure. As shown in FIGS. 4A and 4B, in some embodiments, the display substrate has a first display region 101 and a second display region 102 located at the periphery of the first display region 101, the hollowed-out structures 7 and the cathode selection patterns 8 are located in the first display region 101, and a light transmittance of the first display region 101 is greater than that of the second display region 102.

In the embodiment of the present disclosure, the first display region 101 may be located at a top middle position of the display substrate. The second display region 102 may surround the first display region 101. However, the present embodiment is not limited to this. For example, the first display region 101 may be located at other positions such as an upper left corner or an upper right corner of the display substrate. In addition, the number of the first display regions 101 may be one or more (no corresponding figure is given).

In some embodiments, a shape of the display substrate may be a rectangle, such as a rounded rectangle. The first display region 101 may be circular or elliptical. However, the embodiment of the present disclosure is not limited to this. The first display region 101 may alternatively have other shapes such as a rectangle, a pentagon, or a hexagon.

As an example, the display substrate in the present disclosure is suitable for a full display with camera 6 (FDC) technology, the first display region 101 is used for subsequently installing the FDC 6, and the second display region 102 is a normal display region. In order to ensure that the FDC 6 may receive enough light, and to improve the shooting effect of the FDC 6, the hollowed-out structures 7 are designed in the first display region 101 to improve the light transmittance of the first display region 101. At the moment, the light transmittance of the first display region 101 is greater than that of the second display region 102. Alternatively, the display substrate in the present disclosure satisfying the design of “the light transmittance of the first display region 101 being greater than that of the second display region 102” may be applied to not only a scene of the FDC 6 but also other scenes, which is not limited in the present disclosure.

In some embodiments, the support patterns 4 are disposed in the second display region 102, not in the first display region 101. That is, the support patterns 4 are disposed only in the second display region 102.

In the present disclosure, a size of the first display region 101 is relatively small. Therefore, even though the support patterns 4 are not disposed in the first display region, by relying on the support patterns 4 located in the second display region 102 and close to and surrounding the first display region 101, it can be ensured that a portion of the FMM located in the first display region 101 is not greatly deformed, and the accuracy of the patterns formed in the first display region 101 by the evaporation process can also be effectively ensured. Meanwhile, the second display region 102 is not provided with the support patterns 4, so that the light transmittance of the first display region 101 can be improved to a certain extent.

Referring to FIG. 4A, in some embodiments, the support patterns 4 are evenly distributed within the second display region 102.

Referring to FIG. 4B, in some embodiments, the second display region 102 includes: a first sub-region close to and surrounding the first display region 101 and a second sub-region located on a side of the first sub-region away from the first display region 101, and a density of the support patterns 4 in the first sub-region is greater than that of the support patterns 4 in the second sub-region.

Generally, the greater the density of the support patterns 4 is, the better the support effect on the FMM during the evaporation process is. In the present disclosure, given that no support pattern 4 is disposed in the first display region 101, the support patterns 4 in the first sub-region of the second display region 102 close to the first display region 101 are designed to have the greater density, so that the deformation of the portion of the FMM in the first display region 101 can be effectively reduced or even completely eliminated.

FIG. 5 is another schematic top view of a portion of a display substrate according to an embodiment of the present disclosure. As shown in FIG. 5, unlike the embodiments shown in FIGS. 4A and 4B, in the embodiment shown in FIG. 5, the support patterns 4 are provided not only in the second display region 102, but also in the first display region 101. In the embodiment of the present disclosure, the support patterns 4 are disposed in the first display region 101 to support the FMM, so that the deformation of the portion of the FMM in the first display region 101 can be effectively eliminated.

In some embodiments, a plurality of first repeating units are provided in the first display region and are arranged in an array along a first direction and a second direction. Each first repeating unit includes a plurality of sub-pixels, and at least a part of the first repeating units are provided with support patterns. A ratio of the number of sub-pixels included in a first repeating unit configured with the support patterns to the number of the support patterns in the same first repeating unit is greater than or equal to 2 and less than or equal to 8.

In some embodiments, a plurality of first repeating units are provided in the first display region and are arranged in an array along a first direction and a second direction. Each first repeating unit includes a plurality of sub-pixels, and at least a part of the first repeating units are provided with cathode selection patterns. A ratio of the number of sub-pixels included in a first repeating unit configured with the cathode selection patterns to the number of the cathode selection patterns in the same first repeating unit is greater than or equal to 2 and less than or equal to 8.

The following description will be made in detail in connection with some specific examples.

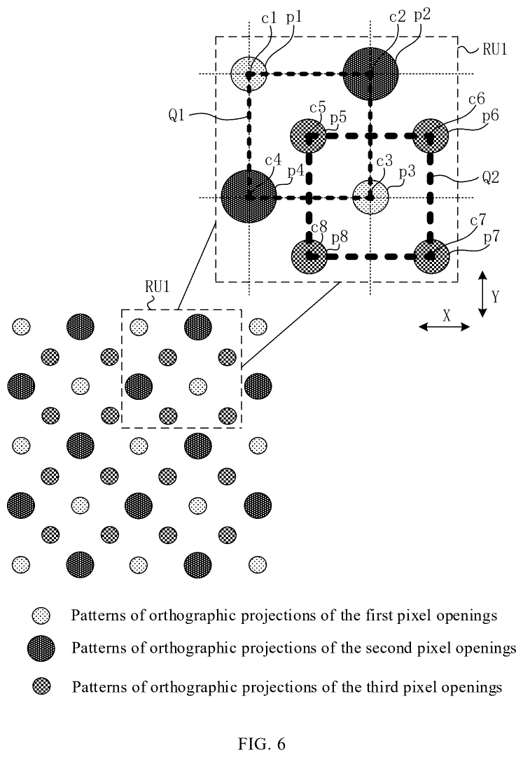

FIG. 6 is a schematic top view of a local region in a first display region in the present disclosure. As shown in FIG. 6, in some embodiments, a plurality of first repeating units RU1 are disposed in the first display region 101 and are arranged in an array along the first direction X and the second direction Y, respectively, and each first repeating unit RU1 includes: two first sub-pixels and two second sub-pixels, a pixel opening 3a corresponding to each first sub-pixel is a first pixel opening 3a, and a pixel opening 3a corresponding to each second sub-pixel is a second pixel opening 3a.

In each first repeating unit RU1, patterns of orthographic projections of the first pixel openings 3a of the two first sub-pixels on the base substrate 1 are a first pattern p1 and a third pattern p3, respectively, patterns of orthographic projections of the second pixel openings 3a of the two second sub-pixels on the base substrate 1 are a second pattern p2 and a fourth pattern p4, respectively, centers of the first pattern p1, the second pattern p2, the third pattern p3 and the fourth pattern p4 are a first center c1, a second center c2, a third center c3 and a fourth center c4, respectively, which are sequentially connected to form a first quadrangle Q1 corresponding to the first repeating unit RU1, and the first quadrangle Q1 is a convex quadrangle.

In some embodiments, the first quadrangle Q1 is a parallelogram, and two sets of opposite sides of the first quadrangle Q1 are parallel to the first direction X and the second direction Y, respectively.

In some embodiments, the first direction X is perpendicular to the second direction Y. In the embodiments of the present disclosure, as an example, the first direction X is a horizontal direction, and the second direction Y is a vertical direction. At this time, the first quadrangle Q1 surrounded by the first center c1, the second center c2, the third center c3, and the fourth center c4 in FIG. 6 is a rectangle (may further alternatively be a square).

In some embodiments, each first repeating unit RU1 further includes: four third sub-pixels, and a pixel opening 3a corresponding to each third sub-pixel is a third pixel opening 3a. Patterns of orthographic projections of the four third pixel openings 3a on the base substrate 1 are a fifth pattern p5, a sixth pattern p6, a seventh pattern p7 and an eighth pattern p8, respectively, the fifth pattern p5 is located inside a region defined by the first quadrangle Q1, and the sixth pattern p6, the seventh pattern p7 and the eighth pattern p8 are located outside the region defined by the first quadrangle Q1. Centers of the fifth pattern p5, the sixth pattern p6, the seventh pattern p7 and the eighth pattern p8 are a fifth center c5, a sixth center c6, a seventh center c7 and an eighth center c8, respectively, which are sequentially connected to form a second quadrangle Q2, and the second quadrangle Q2 is a convex quadrangle.

In some embodiments, the second quadrangle Q2 is a parallelogram, and two sets of opposite sides of the second quadrangle Q2 are parallel to the first direction X and the second direction Y, respectively. In the example shown in FIG. 6, the fifth center c5 is located at a center of the first quadrangle Q1 and the third center c3 is located at a center of the second quadrangle Q2.

Optionally, the second quadrangle Q2 surrounded by the fifth center c5, the sixth center c6, the seventh center c7 and the eighth center c8 is a rectangle. The second quadrangle Q2 may further alternatively be a square.

FIG. 6 only illustrates a layout of the sub-pixels in the first display region 101, which is only an alternative embodiment in the present disclosure, and does not limit the technical solution of the present disclosure.

In some embodiments, at least one first repeating unit RU1 is configured with a corresponding cathode selection pattern 8, and an orthographic projection of the at least one cathode selection pattern 8 corresponding to the first repeating unit RU1 on the base substrate 1 and the region defined by the first quadrangle Q1 corresponding to the first repeating unit RU1 overlap with each other.

The layout of the sub-pixels, the cathode selection patterns 8 and the support patterns 4 in the first display region 101 in the present disclosure will be described in detail with reference to some drawings.

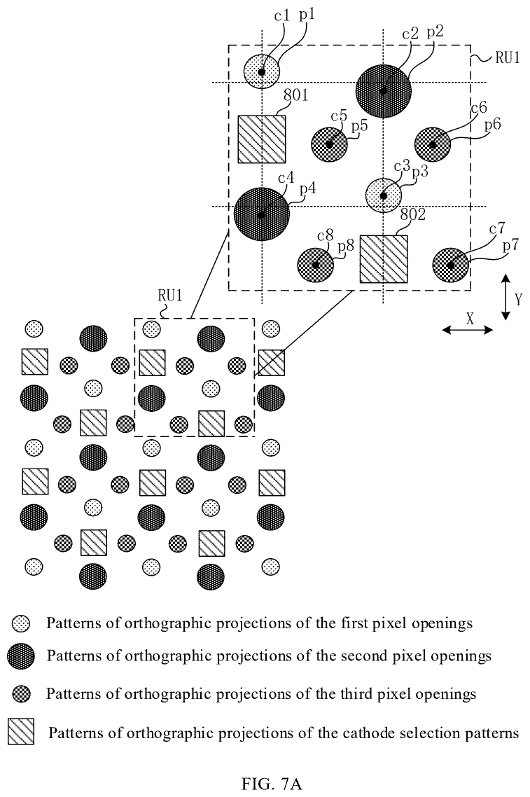

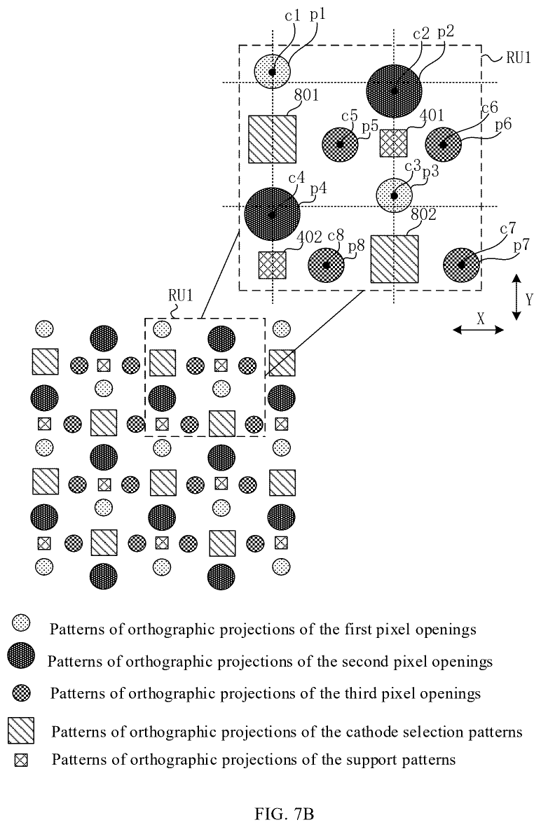

FIG. 7A is a schematic top view of a local region in a first display region 101 according to an embodiment of the present disclosure; FIG. 7B is a schematic top view of a local region with a support pattern in FIG. 7A. As shown in FIGS. 7A and 7B, in each first repeating unit RU1, an extending direction of a line connecting the first center c1 and the fourth center c4 is parallel to the second direction Y, and an extending direction of a line connecting the second center c2 and the third center c3 is parallel to the second direction Y, a minimum distance between the first pattern p1 and the fourth pattern p4 is greater than a minimum distance between the second pattern p2 and the third pattern p3.

Unlike the case shown in FIG. 6, where a distance between the first center c1 and the fourth center c4 in each first repeating unit RU1 is equal to a distance between the second center c2 and the third center c3, in the embodiment as shown in FIGS. 7A and 7B, the distance between the first center c1 and the fourth center c4 in each first repeating unit RU1 is greater than the distance between the second center c2 and the third center c3.

The corresponding cathode selection patterns 8 configured by the first repeating unit RU1 include: at least one of a first cathode selection pattern 801 and a second cathode selection pattern 802.

An orthographic projection of the first cathode selection pattern 801 on the base substrate 1 is located between the first pattern p1 in the corresponding first repeating unit RU1 and the fourth pattern p4 in the corresponding first repeating unit RU1.

In the embodiment as shown in FIGS. 7A and 7B, there is a greater spacing between the first pattern p1 and the fourth pattern p4 located in the same first repeating unit RU1 as the first pattern p1, so that the first cathode selection pattern 801 may be designed at the greater spacing and may have a larger size, which is beneficial to improving the light transmittance of the first display region 101.

An orthographic projection of the second cathode selection pattern 802 on the base substrate 1 is located between the third pattern p3 in the corresponding first repeating unit RU1 and a second pattern p2 adjacent to the third pattern p3 in the second direction Y and in an adjacent first repeating unit RU1.

In the embodiment as shown in FIGS. 7A and 7B, there is a greater spacing between the third pattern p3 and the second pattern p2 adjacent to the third pattern p3 in the second direction Y and in the adjacent first repeating unit RU1, so that the second cathode selection pattern 802 may be designed at the greater spacing and may have a larger size, which is beneficial to improving the light transmittance of the first display region 101.

Referring to FIGS. 7A and 7B, in some embodiments, in each first repeating unit RU1, a ratio of the distance between the first center c1 and the fourth center c4 to the distance between the second center c2 and the third center c3 is greater than 1 and less than or equal to 1.2.

With continued reference to FIGS. 7A and 7B, in some embodiments, the orthographic projection of the first cathode selection pattern 801 on the base substrate 1 is located between the fifth pattern p5 in the corresponding first repeating unit RU1 and a sixth pattern p6 adjacent to the fifth pattern p5 in the first direction X and in an adjacent first repeating unit RU1. The orthographic projection of the second cathode selection pattern 802 on the base substrate 1 is located between the seventh pattern p7 in the corresponding first repeating unit RU1 and the eighth pattern p8 in the corresponding first repeating unit RU1.

With continued reference to FIGS. 7A and 7B, in some embodiments, in each first repeating unit RU1, an extending direction of a line connecting the fifth center c5 and the sixth center c6 is parallel to the first direction X, and an extending direction of a line connecting the seventh center c7 and the eighth center c8 is parallel to the first direction X. A minimum distance between the fifth pattern p5 and the sixth pattern p6 is smaller than a minimum distance between the seventh pattern p7 and the eighth pattern p8.

Unlike the case shown in FIG. 6, where a distance between the fifth center c5 and the sixth center c6 in each first repeating unit RU1 is equal to a distance between the seventh center c7 and the eighth center c8, in the embodiment as shown in FIGS. 7A and 7B, the distance between the fifth center c5 and the sixth center c6 in each first repeating unit RU1 is less than the distance between the seventh center c7 and the eighth center c8. With such the design, there may be a sufficiently large design space for the first cathode selection pattern 801 and the second cathode selection pattern 802.

In some embodiments, in each first repeating unit RU1, a ratio of the distance between the seventh center c7 and the eighth center c8 to the distance between the fifth center c5 and the sixth center c6 is greater than 1 and equal to or less than 1.2.

As shown in FIG. 7B, in some embodiments, at least one first repeating unit RU1 is configured with at least one corresponding support pattern 4. The corresponding support patterns 4 configured by each first repeating unit RU1 include: at least one of a first support pattern 401 and a second support pattern 402. An orthographic projection of the first support pattern 401 on the base substrate 1 is located between the second pattern p2 in the corresponding first repeating unit RU1 and the third pattern p3 in the corresponding first repeating unit RU1. An orthographic projection of the second support pattern 402 on the base substrate 1 is located between the fourth pattern p4 in the corresponding first repeating unit RU1 and a first pattern p1 adjacent to the fourth pattern p4 in the second direction Y and in an adjacent first repeating unit RU1.

With continued reference to FIG. 7B, further optionally, the orthographic projection of the first support pattern 401 on the base substrate 1 is located between the fifth pattern p5 in the corresponding first repeating unit RU1 and the sixth pattern p6 in the corresponding first repeating unit RU1. The orthographic projection of the second support pattern 402 on the base substrate 1 is located between the eighth pattern p8 in the corresponding first repeating unit RU1 and a seventh pattern p7 adjacent to the eighth pattern p8 in the first direction X and in an adjacent first repeating unit RU1.

In the embodiment of the present disclosure, given that a size of each cathode selection pattern 8 may be larger than that of each support pattern 4, a spacing between sub-pixels near each cathode selection pattern 8 may be designed to be relatively large, and a spacing between sub-pixels near each support pattern 4 may be designed to be relatively small.

The layout of the sub-pixels shown in FIGS. 7A and 7B may be regarded as obtained by moving the first pattern p1 and the third pattern p3 in FIG. 6 vertically upward by a distance, moving the second pattern p2 and the fourth pattern p4 vertically downward by a distance, moving the fifth pattern p5 and the seventh pattern p7 horizontally rightward by a distance, and moving the sixth pattern p6 and the eighth pattern p8 horizontally leftward by a distance.

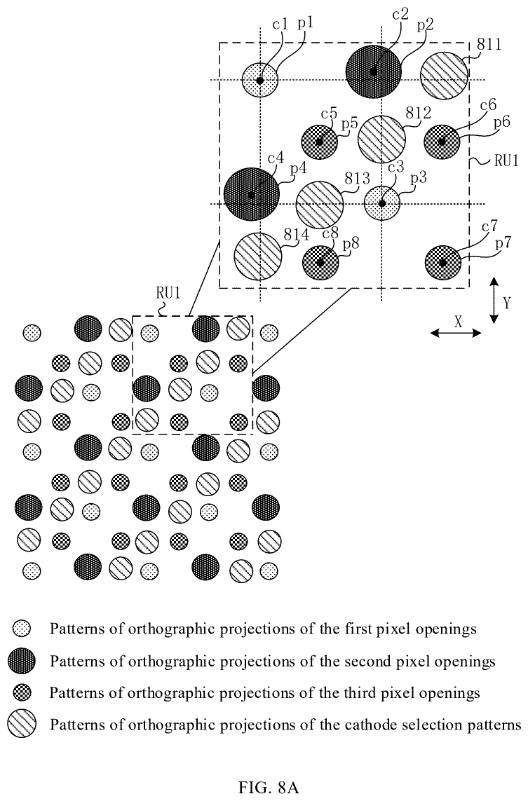

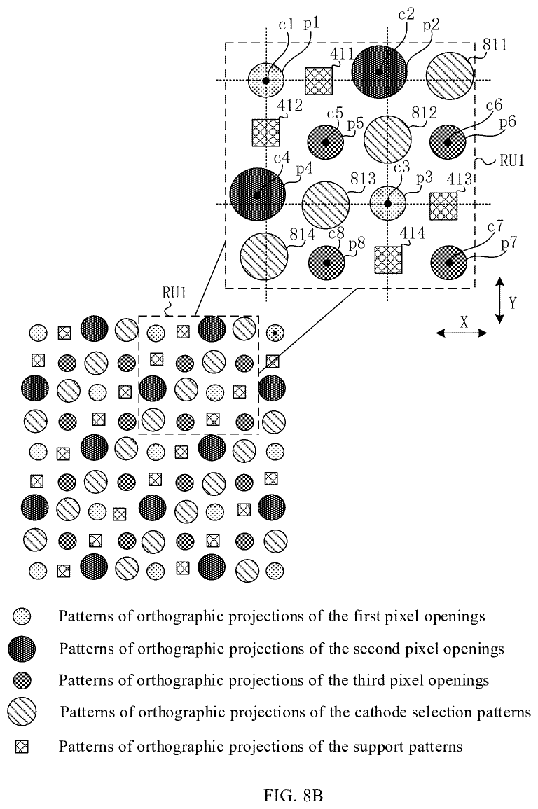

FIG. 8A is another schematic top view of a local region in a first display region 101 according to an embodiment of the present disclosure; FIG. 8B is a schematic top view of a local region with a support pattern in FIG. 8A. As another alternative, as shown in FIGS. 8A and 8B, in some embodiments, in each first repeating unit RU1, a minimum distance between the second pattern p2 and the third pattern p3 is greater than a minimum distance between the second pattern p2 and the first pattern p1, a minimum distance between the fourth pattern p4 and the third pattern p3 is greater than a minimum distance between the fourth pattern p4 and the first pattern p1, and the corresponding cathode selection patterns 8 configured by each first repeating unit RU1 include: at least one of an eleventh cathode selection pattern 811, a twelfth cathode selection pattern 812, a thirteenth cathode selection pattern 813, and a fourteenth cathode selection pattern 814.

An orthographic projection of the eleventh cathode selection pattern 811 on the base substrate 1 is located between the second pattern p2 in the corresponding first repeating unit RU1 and a first pattern p1 adjacent to the second pattern p2 in the first direction X and in an adjacent first repeating unit RU1.

In the embodiment as shown in FIGS. 8A and 8B, there is a greater spacing between the second pattern p2 and the first pattern p1 adjacent to the second pattern p2 in the first direction X and in the adjacent first repeating unit RU1, so that the eleventh cathode selection pattern 811 may be designed at the greater spacing and may have a larger size, which is beneficial to improving the light transmittance of the first display region 101.

An orthographic projection of the twelfth cathode selection pattern 812 on the base substrate 1 is located between the second pattern p2 in the corresponding first repeating unit RU1 and the third pattern p3 in the corresponding first repeating unit RU1.

In the embodiment as shown in FIGS. 8A and 8B, there is a greater spacing between the second pattern p2 and the third pattern p3 located in the same first repeating unit RU1 as the second pattern p2, so that the twelfth cathode selection pattern 812 may be designed at the greater spacing and may have a larger size, which is beneficial to improving the light transmittance of the first display region 101.

An orthographic projection of the thirteenth cathode selection pattern 813 on the base substrate 1 is located between the third pattern p3 in the corresponding first repeating unit RU1 and the fourth pattern p4 in the corresponding first repeating unit RU1.

In the embodiment as shown in FIGS. 8A and 8B, there is a greater spacing between the third pattern p3 and the fourth pattern p4 located in the same first repeating unit RU1 as the third pattern p3, so that the thirteenth cathode selection pattern 813 may be designed at the greater spacing and may have a larger size, which is beneficial to improving the light transmittance of the first display region 101.

An orthographic projection of the fourteenth cathode selection pattern 814 on the base substrate 1 is located between the fourth pattern p4 in the corresponding first repeating unit RU1 and a first pattern p1 adjacent to the fourth pattern p4 in the second direction Y and in an adjacent first repeating unit RU1.

In the embodiment as shown in FIGS. 8A and 8B, there is a greater spacing between the fourth pattern p4 and the first pattern p1 adjacent to the fourth pattern p4 in the second direction Y and in the adjacent first repeating unit RU1, so that the fourteenth cathode selection pattern 814 may be designed at the greater spacing and may have a larger size, which is beneficial to improving the light transmittance of the first display region 101.

Referring to FIGS. 8A and 8B, in some embodiments, in each first repeating unit RU1, a ratio of a distance between the second center c2 and the third center c3 to a distance between the second center c2 and the first center c1 is greater than 1 and less than or equal to 1.2, and a ratio of a distance between the fourth center c4 and the third center c3 to a distance between the fourth center c4 and the first center c1 is greater than 1 and equal to or less than 1.2.

In some embodiments, the minimum distance between the second pattern p2 and the first pattern p1 located in the same first repeating unit RU1 is smaller than a minimum distance between the second pattern p2 and a first pattern p1 located in an adjacent first repeating unit RU1 and adjacent to the second pattern p2 in the first direction X. The minimum distance between the fourth pattern p4 and the first pattern p1 located in the same first repeating unit RU1 is smaller than a minimum distance between the fourth pattern p4 and a first pattern p1 located in an adjacent first repeating unit RU1 and adjacent to the fourth pattern p4 in the second direction Y.

In some embodiments, a ratio of a distance between the second center c2 and a first center c1 located in an adjacent first repeating unit RU1 and adjacent to the second center c2 in the first direction X to the distance between the second center c2 and the first center c1 located in the same first repeating unit RU1 is greater than 1 and equal to or less than 1.2, and a ratio of a distance between the fourth center c4 and a first center c1 located in an adjacent first repeating unit RU1 and adjacent to the fourth center c4 in the second direction Y to the distance between the fourth center c4 and the first center c1 located in the same first repeating unit RU1 is greater than 1 and equal to or less than 1.2.

With continued reference to FIGS. 8A and 8B, in some embodiments, the orthographic projection of the eleventh cathode selection pattern 811 on the base substrate 1 is located between the sixth pattern p6 in the corresponding first repeating unit RU1 and a seventh pattern p7 adjacent to the sixth pattern p6 in the second direction Y and in an adjacent first repeating unit RU1. The orthographic projection of the twelfth cathode selection pattern 812 on the base substrate 1 is located between the fifth pattern p5 in the corresponding first repeating unit RU1 and the sixth pattern p6 in the corresponding first repeating unit RU1. The orthographic projection of the thirteenth cathode selection pattern 813 on the base substrate 1 is located between the fifth pattern p5 in the corresponding first repeating unit RU1 and the eighth pattern p8 in the corresponding first repeating unit RU1. The orthographic projection of the fourteenth cathode selection pattern 814 on the base substrate 1 is located between the eighth pattern p8 in the corresponding first repeating unit RU1 and a seventh pattern p7 adjacent to the eighth pattern p8 in the first direction X and in an adjacent first repeating unit RU1.

Referring to FIG. 8B, in some embodiments, at least one first repeating unit RU1 is configured with at least one corresponding support pattern 4. The corresponding support patterns 4 configured by each first repeating unit RU1 include: at least one of an eleventh support pattern 411, a twelfth support pattern 412, a thirteenth support pattern 413, and a fourteenth support pattern 414.

An orthographic projection of the eleventh support pattern 411 on the base substrate 1 is located between the first pattern p1 in the corresponding first repeating unit RU1 and the second pattern p2 in the corresponding first repeating unit RU1.

An orthographic projection of the twelfth support pattern 412 on the base substrate 1 is located between the first pattern p1 in the corresponding first repeating unit RU1 and the fourth pattern p4 in the corresponding first repeating unit RU1.

An orthographic projection of the thirteenth support pattern 413 on the base substrate 1 is located between the third pattern p3 in the corresponding first repeating unit RU1 and a fourth pattern p4 adjacent to the third pattern p3 in the first direction X and in an adjacent first repeating unit RU1.

An orthographic projection of the fourteenth support pattern 414 on the base substrate 1 is located between the third pattern p3 in the corresponding first repeating unit RU1 and a second pattern p2 adjacent to the third pattern p3 in the second direction Y and in an adjacent first repeating unit RU1.

With continued reference to FIG. 8B, further optionally, the orthographic projection of the eleventh support pattern 411 on the base substrate 1 is located between the fifth pattern p5 in the corresponding first repeating unit RU1 and an eighth pattern p8 adjacent to the fifth pattern p5 in the second direction Y and in an adjacent first repeating unit RU1.

The orthographic projection of the twelfth support pattern 412 on the base substrate 1 is located between the fifth pattern p5 in the corresponding first repeating unit RU1 and a sixth pattern p6 adjacent to the fifth pattern p5 in the first direction X and in an adjacent first repeating unit RU1.

The orthographic projection of the thirteenth support pattern 413 on the base substrate 1 is located between the sixth pattern p6 in the corresponding first repeating unit RU1 and the seventh pattern p7 in the corresponding first repeating unit RU1.

The orthographic projection of the fourteenth support pattern 414 on the base substrate 1 is located between the seventh pattern p7 in the corresponding first repeating unit RU1 and the eighth pattern p8 in the corresponding first repeating unit RU1.

In the embodiment of the present disclosure, given that a size of each cathode selection pattern 8 may be larger than that of each support pattern 4, a spacing between sub-pixels near each cathode selection pattern 8 may be designed to be relatively large, and a spacing between sub-pixels near each support pattern 4 may be designed to be relatively small.

The layout of the sub-pixels shown in FIGS. 8A and 8B may be regarded as obtained by keeping the first pattern p1, the third pattern p3, the fifth pattern p5 to the eighth pattern p8 in FIG. 6 still, and moving the second pattern p2 and the fourth pattern p4 towards an upper left direction by a distance.

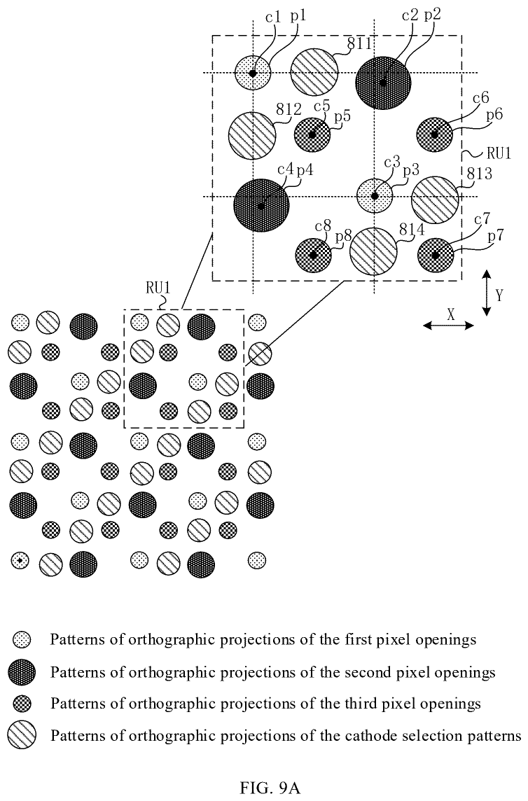

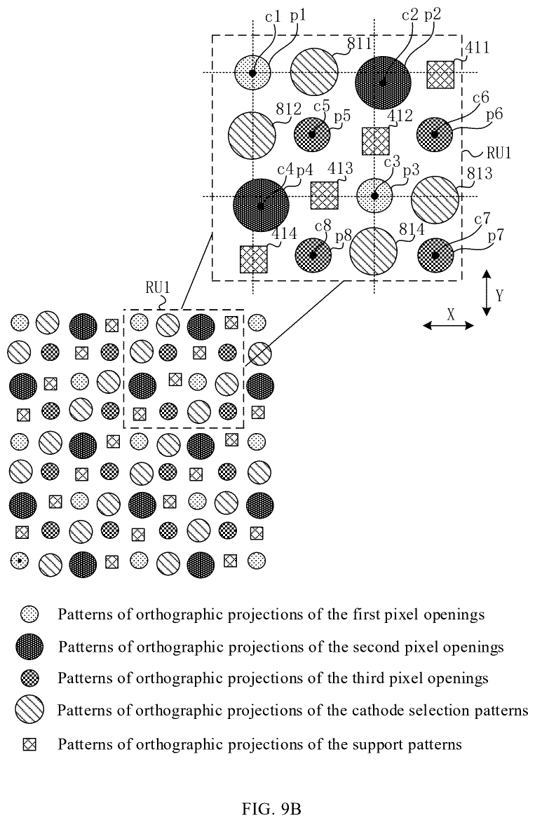

FIG. 9A is another schematic top view of a local region in a first display region 101 according to an embodiment of the present disclosure; FIG. 9B is a schematic top view of a local region with a support pattern in FIG. 9A. As another alternative, as shown in FIGS. 9A and 9B, in some embodiments, in each first repeating unit RU1, a minimum distance between the second pattern p2 and the first pattern p1 is greater than a minimum distance between the second pattern p2 and the third pattern p3, and a minimum distance between the fourth pattern p4 and the first pattern p1 is greater than a minimum distance between the fourth pattern p4 and the third pattern p3.

The corresponding cathode selection patterns 8 configured by each first repeating unit RU1 include: at least one of an eleventh cathode selection pattern 811, a twelfth cathode selection pattern 812, a thirteenth cathode selection pattern 813, and a fourteenth cathode selection pattern 814.

An orthographic projection of the eleventh cathode selection pattern 811 on the base substrate 1 is located between the first pattern p1 in the corresponding first repeating unit RU1 and the second pattern p2 in the corresponding first repeating unit RU1.

In the embodiment as shown in FIGS. 9A and 9B, there is a greater spacing between the first pattern p1 and the second pattern p2 located in the same first repeating unit RU1 as the first pattern p1, so that the eleventh cathode selection pattern 811 may be designed at the greater spacing and may have a larger size, which is beneficial to improving the light transmittance of the first display region 101.

An orthographic projection of the twelfth cathode selection pattern 812 on the base substrate 1 is located between the first pattern p1 in the corresponding first repeating unit RU1 and the fourth pattern p4 in the corresponding first repeating unit RU1.

In the embodiment as shown in FIGS. 9A and 9B, there is a greater spacing between the first pattern p1 and the fourth pattern p4 located in the same first repeating unit RU1 as the first pattern p1, so that the twelfth cathode selection pattern 812 may be designed at the greater spacing and may have a larger size, which is beneficial to improving the light transmittance of the first display region 101.

An orthographic projection of the thirteenth cathode selection pattern 813 on the base substrate 1 is located between the third pattern p3 in the corresponding first repeating unit RU1 and a fourth pattern p4 adjacent to the third pattern p3 in the first direction X and in an adjacent first repeating unit RU1.

In the embodiment as shown in FIGS. 9A and 9B, there is a greater spacing between the third pattern p3 and the fourth pattern p4 adjacent to the third pattern p3 in the first direction X and in the adjacent first repeating unit RU1, so that the thirteenth cathode selection pattern 813 may be designed at the greater spacing and may have a larger size, which is beneficial to improving the light transmittance of the first display region 101.

An orthographic projection of the fourteenth cathode selection pattern 814 on the base substrate 1 is located between the third pattern p3 in the corresponding first repeating unit RU1 and a second pattern p2 adjacent to the third pattern p3 in the second direction Y and in an adjacent first repeating unit RU1.

In the embodiment as shown in FIGS. 9A and 9B, there is a greater spacing between the third pattern p3 and the second pattern p2 adjacent to the third pattern p3 in the second direction Y and in the adjacent first repeating unit RU1, so that the fourteenth cathode selection pattern 814 may be designed at the greater spacing and may have a larger size, which is beneficial to improving the light transmittance of the first display region 101.

Referring to FIGS. 9A and 9B, in some embodiments, in each first repeating unit RU1, a ratio of a distance between the second center c2 and the first center c1 to a distance between the second center c2 and the third center c3 is greater than 1 and less than or equal to 1.2, and a ratio of a distance between the fourth center c4 and the first center c1 to a distance between the fourth center c4 and the third center c3 is greater than 1 and equal to or less than 1.2.

In some embodiments, the minimum distance between the third pattern p3 and the second pattern p2 located in the same first repeating unit RU1 is smaller than a minimum distance between the third pattern p3 and a second pattern p2 located in an adjacent first repeating unit RU1 and adjacent to the third pattern p3 in the second direction Y. The minimum distance between the third pattern p3 and the fourth pattern p4 located in the same first repeating unit RU1 is smaller than a minimum distance between the third pattern p3 and a fourth pattern p4 located in an adjacent first repeating unit RU1 and adjacent to the third pattern p3 in the first direction X.

In some embodiments, a ratio of a distance between the third center c3 and a second center c2 located in an adjacent first repeating unit RU1 and adjacent to the third center c3 in the second direction Y to the distance between the third center c3 and the second center c2 located in the same first repeating unit RU1 is greater than 1 and equal to or less than 1.2, and a ratio of a distance between the third center c3 and a fourth center c4 located in an adjacent first repeating unit RU1 and adjacent to the third center c3 in the first direction X to the distance between the third center c3 and the fourth center c4 located in the same first repeating unit RU1 is greater than 1 and equal to or less than 1.2.

With continued reference to FIGS. 9A and 9B, in some embodiments, the orthographic projection of the eleventh cathode selection pattern 811 on the base substrate 1 is located between the fifth pattern p5 in the corresponding first repeating unit RU1 and an eighth pattern p8 adjacent to the fifth pattern p5 in the second direction Y and in an adjacent first repeating unit RU1. The orthographic projection of the twelfth cathode selection pattern 812 on the base substrate 1 is located between the fifth pattern p5 in the corresponding first repeating unit RU1 and a sixth pattern p6 adjacent to the fifth pattern p5 in the first direction X and in an adjacent first repeating unit RU1. The orthographic projection of the thirteenth cathode selection pattern 813 on the base substrate 1 is located between the sixth pattern p6 in the corresponding first repeating unit RU1 and the seventh pattern p7 in the corresponding first repeating unit RU1. The orthographic projection of the fourteenth cathode selection pattern 814 on the base substrate 1 is located between the seventh pattern p7 in the corresponding first repeating unit RU1 and the eighth pattern p8 in the corresponding first repeating unit RU1.

Referring to FIG. 9B, in some embodiments, at least one first repeating unit RU1 is configured with at least one corresponding support pattern 4. The corresponding support patterns 4 configured by each first repeating unit RU1 include: at least one of an eleventh support pattern 411, a twelfth support pattern 412, a thirteenth support pattern 413, and a fourteenth support pattern 414.

An orthographic projection of the eleventh support pattern 411 on the base substrate 1 is located between the second pattern p2 in the corresponding first repeating unit RU1 and a first pattern p1 adjacent to the second pattern p2 in the first direction X and in an adjacent first repeating unit RU1.

An orthographic projection of the twelfth support pattern 412 on the base substrate 1 is located between the second pattern p2 in the corresponding first repeating unit RU1 and the third pattern p3 in the corresponding first repeating unit RU1.

An orthographic projection of the thirteenth support pattern 413 on the base substrate 1 is located between the third pattern p3 in the corresponding first repeating unit RU1 and the fourth pattern p4 in the corresponding first repeating unit RU1.

An orthographic projection of the fourteenth support pattern 414 on the base substrate 1 is located between the fourth pattern p4 in the corresponding first repeating unit RU1 and a first pattern p1 adjacent to the fourth pattern p4 in the second direction Y and in an adjacent first repeating unit RU1.

With continued reference to FIG. 9B, further optionally, the orthographic projection of the eleventh support pattern 411 on the base substrate 1 is located between the sixth pattern p6 in the corresponding first repeating unit RU1 and a seventh pattern p7 adjacent to the sixth pattern p6 in the second direction Y and in an adjacent first repeating unit RU1.

The orthographic projection of the twelfth support pattern 412 on the base substrate 1 is located between the fifth pattern p5 in the corresponding first repeating unit RU1 and the sixth pattern p6 in the corresponding first repeating unit RU1.

The orthographic projection of the thirteenth support pattern 413 on the base substrate 1 is located between the fifth pattern p5 in the corresponding first repeating unit RU1 and the eighth pattern p8 in the corresponding first repeating unit RU1.

The orthographic projection of the fourteenth support pattern 414 on the base substrate 1 is located between the eighth pattern p8 in the corresponding first repeating unit RU1 and a seventh pattern p7 adjacent to the eighth pattern p8 in the first direction X and in an adjacent first repeating unit RU1.

In the embodiment of the present disclosure, given that a size of each cathode selection pattern 8 may be larger than that of each support pattern 4, a spacing between sub-pixels near each cathode selection pattern 8 may be designed to be relatively large, and a spacing between sub-pixels near each support pattern 4 may be designed to be relatively small.

The layout of the sub-pixels shown in FIGS. 9A and 9B may be regarded as obtained by keeping the first pattern p1, the third pattern p3, the fifth pattern p5 to the eighth pattern p8 in FIG. 6 still, and moving the second pattern p2 and the fourth pattern p4 towards a lower right direction by a distance.

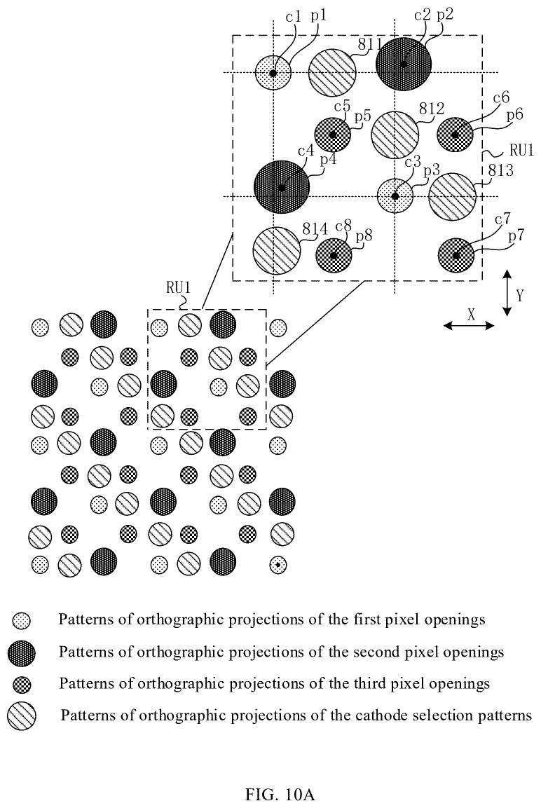

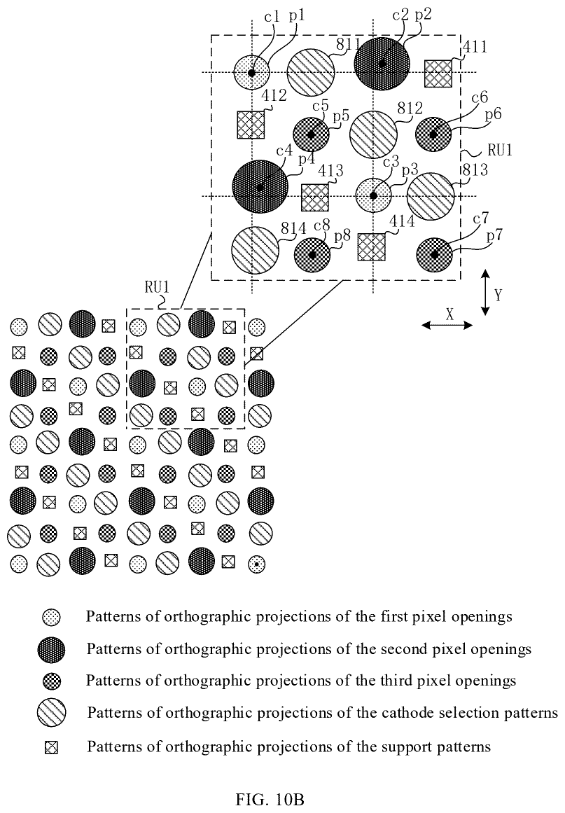

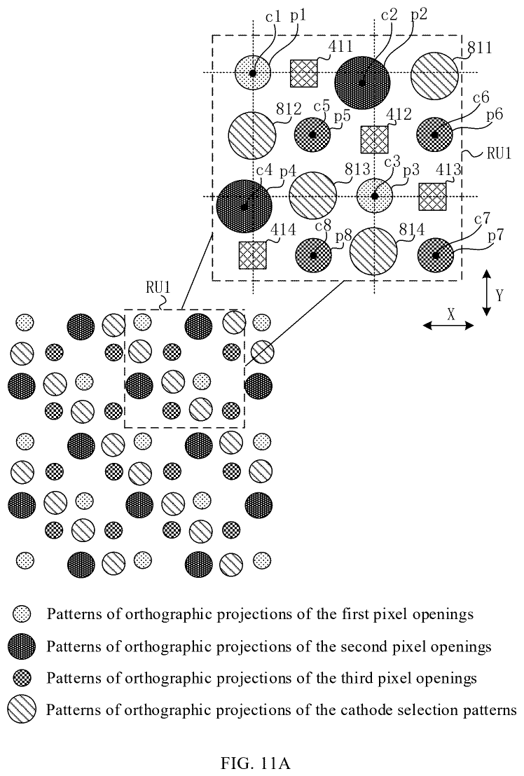

FIG. 10A is another schematic top view of a local region in a first display region 101 according to an embodiment of the present disclosure; FIG. 10B is a schematic top view of a local region with a support pattern in FIG. 10A. As another alternative, as shown in FIGS. 10A and 10B, in some embodiments, in each first repeating unit RU1, a minimum distance between the first pattern p1 and the second pattern p2 is greater than a minimum distance between the first pattern p1 and the fourth pattern p4, and a minimum distance between the third pattern p3 and the second pattern p2 is greater than a minimum distance between the third pattern p3 and the fourth pattern p4.

The corresponding cathode selection patterns 8 configured by each first repeating unit RU1 include: at least one of an eleventh cathode selection pattern 811, a twelfth cathode selection pattern 812, a thirteenth cathode selection pattern 813, and a fourteenth cathode selection pattern 814.

An orthographic projection of the eleventh cathode selection pattern 811 on the base substrate 1 is located between the first pattern p1 in the corresponding first repeating unit RU1 and the second pattern p2 in the corresponding first repeating unit RU1.

In the embodiment as shown in FIGS. 10A and 10B, there is a greater spacing between the first pattern p1 and the second pattern p2 located in the same first repeating unit RU1 as the first pattern p1, so that the eleventh cathode selection pattern 811 may be designed at the greater spacing and may have a larger size, which is beneficial to improving the light transmittance of the first display region 101.

An orthographic projection of the twelfth cathode selection pattern 812 on the base substrate 1 is located between the second pattern p2 in the corresponding first repeating unit RU1 and the third pattern p3 in the corresponding first repeating unit RU1.

In the embodiment as shown in FIGS. 10A and 10B, there is a greater spacing between the second pattern p2 and the third pattern p3 located in the same first repeating unit RU1 as the second pattern p2, so that the twelfth cathode selection pattern 812 may be designed at the greater spacing and may have a larger size, which is beneficial to improving the light transmittance of the first display region 101.

An orthographic projection of the thirteenth cathode selection pattern 813 on the base substrate 1 is located between the third pattern p3 in the corresponding first repeating unit RU1 and a fourth pattern p4 adjacent to the third pattern p3 in the first direction X and in an adjacent first repeating unit RU1.

In the embodiment as shown in FIGS. 10A and 10B, there is a greater spacing between the third pattern p3 and the fourth pattern p4 adjacent to the third pattern p3 in the first direction X and in the adjacent first repeating unit RU1, so that the thirteenth cathode selection pattern 813 may be designed at the greater spacing and may have a larger size, which is beneficial to improving the light transmittance of the first display region 101.

An orthographic projection of the fourteenth cathode selection pattern 814 on the base substrate 1 is located between the fourth pattern p4 in the corresponding first repeating unit RU1 and a first pattern p1 adjacent to the fourth pattern p4 in the second direction Y and in an adjacent first repeating unit RU1.

In the embodiment as shown in FIGS. 10A and 10B, there is a greater spacing between the fourth pattern p4 and the first pattern p1 adjacent to the fourth pattern p4 in the second direction Y and in the adjacent first repeating unit RU1, so that the fourteenth cathode selection pattern 814 may be designed at the greater spacing and may have a larger size, which is beneficial to improving the light transmittance of the first display region 101.

Referring to FIGS. 10A and 10B, in some embodiments, in each first repeating unit RU1, a ratio of a distance between the first center c1 and the second center c2 to a distance between the first center c1 and the fourth center c4 is greater than 1 and less than or equal to 1.2, and a ratio of a distance between the third center c3 and the second center c2 to a distance between the third center c3 and the fourth center c4 is greater than 1 and equal to or less than 1.2.

In some embodiments, the minimum distance between the fourth pattern p4 and the first pattern p1 located in the same first repeating unit RU1 is smaller than a minimum distance between the fourth pattern p4 and a first pattern p1 located in an adjacent first repeating unit RU1 and adjacent to the fourth pattern p4 in the second direction Y. The minimum distance between the fourth pattern p4 and the third pattern p3 located in the same first repeating unit RU1 is smaller than a minimum distance between the fourth pattern p4 and a third pattern p3 located in an adjacent first repeating unit RU1 and adjacent to the fourth pattern p4 in the first direction X.

In some embodiments, a ratio of a distance between the fourth center c4 and a first center c1 located in an adjacent first repeating unit RU1 and adjacent to the fourth center c4 in the second direction Y to the distance between the fourth center c4 and the first center c1 located in the same first repeating unit RU1 is greater than 1 and equal to or less than 1.2, and a ratio of a distance between the fourth center c4 and a third center c3 located in an adjacent first repeating unit RU1 and adjacent to the fourth center c4 in the first direction X to the distance between the third center c3 and the fourth center c4 located in the same first repeating unit RU1 is greater than 1 and equal to or less than 1.2.

With continued reference to FIGS. 10A and 10B, in some embodiments, the orthographic projection of the eleventh cathode selection pattern 811 on the base substrate 1 is located between the fifth pattern p5 in the corresponding first repeating unit RU1 and an eighth pattern p8 adjacent to the fifth pattern p5 in the second direction Y and in an adjacent first repeating unit RU1. The orthographic projection of the twelfth cathode selection pattern 812 on the base substrate 1 is located between the fifth pattern p5 in the corresponding first repeating unit RU1 and the sixth pattern p6 in the corresponding first repeating unit RU1. The orthographic projection of the thirteenth cathode selection pattern 813 on the base substrate 1 is located between the sixth pattern p6 in the corresponding first repeating unit RU1 and the seventh pattern p7 in the corresponding first repeating unit RU1. The orthographic projection of the fourteenth cathode selection pattern 814 on the base substrate 1 is located between the eighth pattern p8 in the corresponding first repeating unit RU1 and a seventh pattern p7 adjacent to the eighth pattern p8 in the first direction X and in an adjacent first repeating unit RU1.

Referring to FIG. 10B, in some embodiments, at least one first repeating unit RU1 is configured with at least one corresponding support pattern 4. The corresponding support patterns 4 configured by each first repeating unit RU1 include: at least one of an eleventh support pattern 411, a twelfth support pattern 412, a thirteenth support pattern 413, and a fourteenth support pattern 414.

An orthographic projection of the eleventh support pattern 411 on the base substrate 1 is located between the second pattern p2 in the corresponding first repeating unit RU1 and a first pattern p1 adjacent to the second pattern p2 in the first direction X and in an adjacent first repeating unit RU1.

An orthographic projection of the twelfth support pattern 412 on the base substrate 1 is located between the first pattern p1 in the corresponding first repeating unit RU1 and the fourth pattern p4 in the corresponding first repeating unit RU1.

An orthographic projection of the thirteenth support pattern 413 on the base substrate 1 is located between the third pattern p3 in the corresponding first repeating unit RU1 and the fourth pattern p4 in the corresponding first repeating unit RU1.

An orthographic projection of the fourteenth support pattern 414 on the base substrate 1 is located between the third pattern p3 in the corresponding first repeating unit RU1 and a second pattern p2 adjacent to the third pattern p3 in the second direction Y and in an adjacent first repeating unit RU1.

With continued reference to FIG. 10B, further optionally, the orthographic projection of the eleventh support pattern 411 on the base substrate 1 is located between the sixth pattern p6 in the corresponding first repeating unit RU1 and a seventh pattern p7 adjacent to the sixth pattern p6 in the second direction Y and in an adjacent first repeating unit RU1.

The orthographic projection of the twelfth support pattern 412 on the base substrate 1 is located between the fifth pattern p5 in the corresponding first repeating unit RU1 and a sixth pattern p6 adjacent to the fifth pattern p5 in the first direction X and in an adjacent first repeating unit RU1.

The orthographic projection of the thirteenth support pattern 413 on the base substrate 1 is located between the fifth pattern p5 in the corresponding first repeating unit RU1 and the eighth pattern p8 in the corresponding first repeating unit RU1.

The orthographic projection of the fourteenth support pattern 414 on the base substrate 1 is located between the seventh pattern p7 in the corresponding first repeating unit RU1 and the eighth pattern p8 in the corresponding first repeating unit RU1.

In the embodiment of the present disclosure, given that a size of each cathode selection pattern 8 may be larger than that of each support pattern 4, a spacing between sub-pixels near each cathode selection pattern 8 may be designed to be relatively large, and a spacing between sub-pixels near each support pattern 4 may be designed to be relatively small.

The layout of the sub-pixels shown in FIGS. 10A and 10B may be regarded as obtained by keeping the first pattern p1, the third pattern p3, the fifth pattern p5 to the eighth pattern p8 in FIG. 6 still, and moving the second pattern p2 and the fourth pattern p4 towards an upper right direction by a distance.

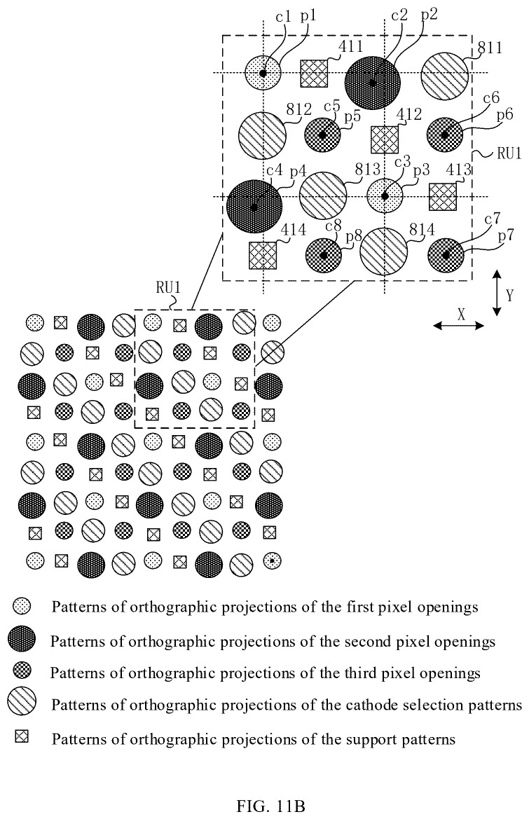

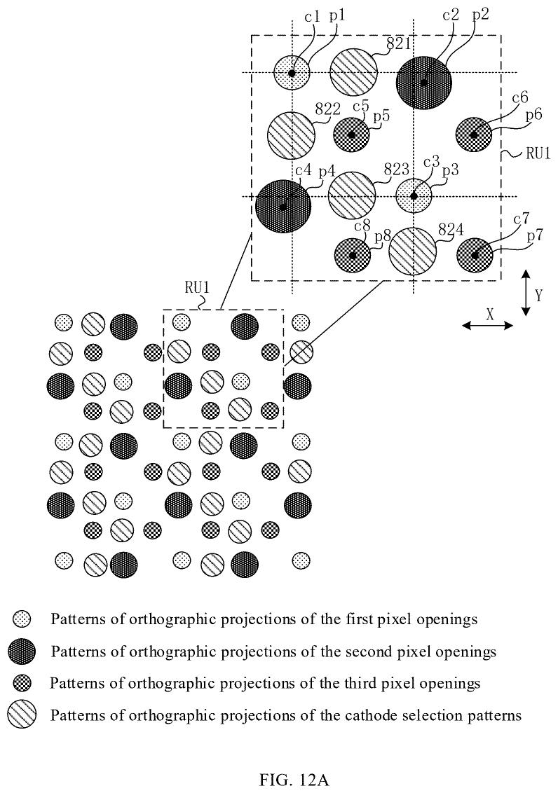

FIG. 11A is another schematic top view of a local region in a first display region 101 according to an embodiment of the present disclosure; FIG. 11B is a schematic top view of a local region with a support pattern in FIG. 11A. As another alternative, as shown in FIGS. 11A and 11B, in some embodiments, in each first repeating unit RU1, a minimum distance between the first pattern p1 and the fourth pattern p4 is greater than a minimum distance between the first pattern p1 and the second pattern p2, and a minimum distance between the third pattern p3 and the fourth pattern p4 is greater than a minimum distance between the third pattern p3 and the second pattern p2.

The corresponding cathode selection patterns 8 configured by each first repeating unit RU1 include: at least one of an eleventh cathode selection pattern 811, a twelfth cathode selection pattern 812, a thirteenth cathode selection pattern 813, and a fourteenth cathode selection pattern 814.

An orthographic projection of the eleventh cathode selection pattern 811 on the base substrate 1 is located between the second pattern p2 in the corresponding first repeating unit RU1 and a first pattern p1 adjacent to the second pattern p2 in the first direction X and in an adjacent first repeating unit RU1.

In the embodiment as shown in FIGS. 11A and 11B, there is a greater spacing between the second pattern p2 and the first pattern p1 adjacent to the second pattern p2 in the first direction X and in the adjacent first repeating unit RU1, so that the eleventh cathode selection pattern 811 may be designed at the greater spacing and may have a larger size, which is beneficial to improving the light transmittance of the first display region 101.

An orthographic projection of the twelfth cathode selection pattern 812 on the base substrate 1 is located between the first pattern p1 in the corresponding first repeating unit RU1 and the fourth pattern p4 in the corresponding first repeating unit RU1.

In the embodiment as shown in FIGS. 11A and 11B, there is a greater spacing between the first pattern p1 and the fourth pattern p4 located in the same first repeating unit RU1 as the first pattern p1, so that the twelfth cathode selection pattern 812 may be designed at the greater spacing and may have a larger size, which is beneficial to improving the light transmittance of the first display region 101.

An orthographic projection of the thirteenth cathode selection pattern 813 on the base substrate 1 is located between the third pattern p3 in the corresponding first repeating unit RU1 and the fourth pattern p4 in the corresponding first repeating unit RU1.

In the embodiment as shown in FIGS. 11A and 11B, there is a greater spacing between the third pattern p3 and the fourth pattern p4 located in the same first repeating unit RU1 as the third pattern p3, so that the thirteenth cathode selection pattern 813 may be designed at the greater spacing and may have a larger size, which is beneficial to improving the light transmittance of the first display region 101.

An orthographic projection of the fourteenth cathode selection pattern 814 on the base substrate 1 is located between the third pattern p3 in the corresponding first repeating unit RU1 and a second pattern p2 adjacent to the third pattern p3 in the second direction Y and in an adjacent first repeating unit RU1.

In the embodiment as shown in FIGS. 11A and 11B, there is a greater spacing between the third pattern p3 and the second pattern p2 adjacent to the third pattern p3 in the second direction Y and in the adjacent first repeating unit RU1, so that the fourteenth cathode selection pattern 814 may be designed at the greater spacing and may have a larger size, which is beneficial to improving the light transmittance of the first display region 101.

Referring to FIGS. 11A and 11B, in some embodiments, in each first repeating unit RU1, a ratio of a distance between the first center c1 and the fourth center c4 to a distance between the first center c1 and the second center c2 is greater than 1 and less than or equal to 1.2, and a ratio of a distance between the third center c3 and the fourth center c4 to a distance between the third center c3 and the second center c2 is greater than 1 and less than or equal to 1.2.

In some embodiments, the minimum distance between the second pattern p2 and the first pattern p1 located in the same first repeating unit RU1 is smaller than a minimum distance between the second pattern p2 and a first pattern p1 located in an adjacent first repeating unit RU1 and adjacent to the second pattern p2 in the first direction X. The minimum distance between the third pattern p3 and the second pattern p2 located in the same first repeating unit RU1 is smaller than a minimum distance between the third pattern p3 and a second pattern p2 located in an adjacent first repeating unit RU1 and adjacent to the third pattern p3 in the second direction Y.

In some embodiments, a ratio of a distance between the second center c2 and a first center c1 located in an adjacent first repeating unit RU1 and adjacent to the second center c2 in the second direction Y to the distance between the second center c2 and the first center c1 located in the same first repeating unit RU1 is greater than 1 and equal to or less than 1.2, and a ratio of a distance between the third center c3 and a second center c2 located in an adjacent first repeating unit RU1 and adjacent to the third center c3 in the first direction X to the distance between the third center c3 and the second center c2 located in the same first repeating unit RU1 is greater than 1 and equal to or less than 1.2.

With continued reference to FIGS. 11A and 11B, in some embodiments, the orthographic projection of the eleventh cathode selection pattern 811 on the base substrate 1 is located between the sixth pattern p6 in the corresponding first repeating unit RU1 and a seventh pattern p7 adjacent to the sixth pattern p6 in the second direction Y and in an adjacent first repeating unit RU1. The orthographic projection of the twelfth cathode selection pattern 812 on the base substrate 1 is located between the fifth pattern p5 in the corresponding first repeating unit RU1 and a sixth pattern p6 adjacent to the fifth pattern p5 in the first direction X and in an adjacent first repeating unit RU1. The orthographic projection of the thirteenth cathode selection pattern 813 on the base substrate 1 is located between the fifth pattern p5 in the corresponding first repeating unit RU1 and the eighth pattern p8 in the corresponding first repeating unit RU1. The orthographic projection of the fourteenth cathode selection pattern 814 on the base substrate 1 is located between the seventh pattern p7 in the corresponding first repeating unit RU1 and the eighth pattern p8 in the corresponding first repeating unit RU1.

Referring to FIG. 11B, in some embodiments, at least one first repeating unit RU1 is configured with at least one corresponding support pattern 4. The corresponding support patterns 4 configured by each first repeating unit RU1 include: at least one of an eleventh support pattern 411, a twelfth support pattern 412, a thirteenth support pattern 413, and a fourteenth support pattern 414.

An orthographic projection of the eleventh support pattern 411 on the base substrate 1 is located between the first pattern p1 in the corresponding first repeating unit RU1 and the second pattern p2 in the corresponding first repeating unit RU1.

An orthographic projection of the twelfth support pattern 412 on the base substrate 1 is located between the second pattern p2 in the corresponding first repeating unit RU1 and the third pattern p3 in the corresponding first repeating unit RU1.

An orthographic projection of the thirteenth support pattern 413 on the base substrate 1 is located between the third pattern p3 in the corresponding first repeating unit RU1 and a fourth pattern p4 adjacent to the third pattern p3 in the first direction X and in an adjacent first repeating unit RU1.

An orthographic projection of the fourteenth support pattern 414 on the base substrate 1 is located between the fourth pattern p4 in the corresponding first repeating unit RU1 and a first pattern p1 adjacent to the fourth pattern p4 in the second direction Y and in an adjacent first repeating unit RU1.

With continued reference to FIG. 11B, further optionally, the orthographic projection of the eleventh support pattern 411 on the base substrate 1 is located between the fifth pattern p5 in the corresponding first repeating unit RU1 and an eighth pattern p8 adjacent to the fifth pattern p5 in the second direction Y and in an adjacent first repeating unit RU1.

The orthographic projection of the twelfth support pattern 412 on the base substrate 1 is located between the fifth pattern p5 in the corresponding first repeating unit RU1 and the sixth pattern p6 in the corresponding first repeating unit RU1.

The orthographic projection of the thirteenth support pattern 413 on the base substrate 1 is located between the sixth pattern p6 in the corresponding first repeating unit RU1 and the seventh pattern p7 in the corresponding first repeating unit RU1.

The orthographic projection of the fourteenth support pattern 414 on the base substrate 1 is located between the eighth pattern p8 in the corresponding first repeating unit RU1 and a seventh pattern p7 adjacent to the eighth pattern p8 in the first direction X and in an adjacent first repeating unit RU1.

In the embodiment of the present disclosure, given that a size of each cathode selection pattern 8 may be larger than that of each support pattern 4, a spacing between sub-pixels near each cathode selection pattern 8 may be designed to be relatively large, and a spacing between sub-pixels near each support pattern 4 may be designed to be relatively small.

The layout of the sub-pixels shown in FIGS. 11A and 11B may be regarded as obtained by keeping the first pattern p1, the third pattern p3, the fifth pattern p5 to the eighth pattern p8 in FIG. 6 still, and moving the second pattern p2 and the fourth pattern p4 towards a lower left direction by a distance.

Note that in the layout of the sub-pixels in FIGS. 8A to 11B, the first pattern p1, the third pattern p3, the fifth pattern p5 to the eighth pattern p8 in FIG. 6 may be kept still, and the second pattern p2 and the fourth pattern p4 may be moved in a specific direction at the same time. Therefore, the display substrate shown in each of FIGS. 8A to 11B may be manufactured by using the same mask used in the manufacturing process shown in FIG. 6, and it is only necessary to move a mask used for forming a structure associated with the second sub-pixel (the second pattern p2 and the fourth pattern p4) by a distance along a specific direction in the corresponding manufacturing process.

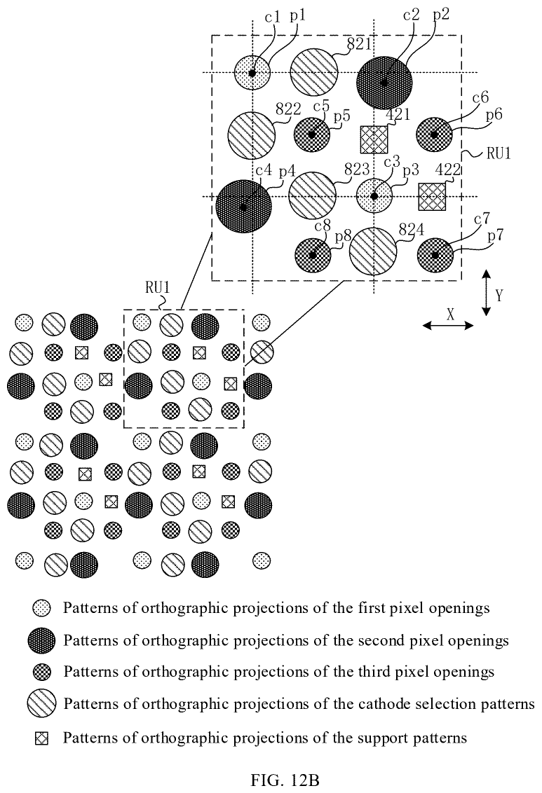

FIG. 12A is another schematic top view of a local region in a first display region 101 according to an embodiment of the present disclosure; FIG. 12B is a schematic top view of a local region with a support pattern in FIG. 12A. As another alternative, as shown in FIGS. 12A and 12B, in some embodiments, in each first repeating unit RU1, a minimum distance between the first pattern p1 and the second pattern p2 is greater than a minimum distance between the second pattern p2 and the third pattern p3, a minimum distance between the first pattern p1 and the fourth pattern p4 is greater than the minimum distance between the second pattern p2 and the third pattern p3, and a minimum distance between the fourth pattern p4 and the third pattern p3 is greater than the minimum distance between the second pattern p2 and the third pattern p3.

The corresponding cathode selection patterns 8 configured by each first repeating unit RU1 include: at least one of a twenty-first cathode selection pattern 821, a twenty-second cathode selection pattern 822, a twenty-third cathode selection pattern 823, and a twenty-fourth cathode selection pattern 824.

An orthographic projection of the twenty-first cathode selection pattern 821 on the base substrate 1 is located between the first pattern p1 in the corresponding first repeating unit RU1 and the second pattern p2 in the corresponding first repeating unit RU1.

In the embodiment as shown in FIGS. 12A and 12B, there is a greater spacing between the first pattern p1 and the second pattern p2 located in the same first repeating unit RU1 as the first pattern p1, so that the twenty-first cathode selection pattern 821 may be designed at the greater spacing and may have a larger size, which is beneficial to improving the light transmittance of the first display region 101.

An orthographic projection of the twenty-second cathode selection pattern 822 on the base substrate 1 is located between the first pattern p1 in the corresponding first repeating unit RU1 and the fourth pattern p4 in the corresponding first repeating unit RU1.

In the embodiment as shown in FIGS. 12A and 12B, there is a greater spacing between the first pattern p1 and the fourth pattern p4 located in the same first repeating unit RU1 as the first pattern p1, so that the twenty-second cathode selection pattern 822 may be designed at the greater spacing and may have a larger size, which is beneficial to improving the light transmittance of the first display region 101.

An orthographic projection of the twenty-third cathode selection pattern 823 on the base substrate 1 is located between the third pattern p3 in the corresponding first repeating unit RU1 and the fourth pattern p4 in the corresponding first repeating unit RU1.

In the embodiment as shown in FIGS. 12A and 12B, there is a greater spacing between the third pattern p3 and the fourth pattern p4 located in the same first repeating unit RU1 as the first pattern p1, so that the twenty-third cathode selection pattern 823 may be designed at the greater spacing and may have a larger size, which is beneficial to improving the light transmittance of the first display region 101.

An orthographic projection of the twenty-fourth cathode selection pattern 824 on the base substrate 1 is located between the third pattern p3 in the corresponding first repeating unit RU1 and a second pattern p2 adjacent to the third pattern p3 in the second direction Y and in an adjacent first repeating unit RU1.

In the embodiment as shown in FIGS. 12A and 12B, there is a greater spacing between the third pattern p3 and the second pattern p2 adjacent to the third pattern p3 in the second direction Y and in the adjacent first repeating unit RU1, so that the twenty-fourth cathode selection pattern 824 may be designed at the greater spacing and may have a larger size, which is beneficial to improving the light transmittance of the first display region 101.

Referring to FIGS. 12A and 12B, in some embodiments, in each first repeating unit RU1, a ratio of a distance between the first center c1 and the second center c2 to a distance between the second center c2 and the third center c3 is greater than 1 and less than or equal to 1.2, a ratio of a distance between the first center c1 and the fourth center c4 to a distance between the second center c2 and the third center c3 is greater than 1 and equal to or less than 1.2, and a ratio of a distance between the fourth center c4 and the third center c3 to a distance between the second center c2 and the third center c3 is greater than 1 and equal to or less than 1.2.

In some embodiments, the minimum distance between the second pattern p2 and the third pattern p3 located in the same first repeating unit RU1 is smaller than a minimum distance between the second pattern p2 and a third pattern p3 located in an adjacent first repeating unit RU1 and adjacent to the second pattern p2 in the second direction Y.

In some embodiments, a ratio of a distance between the second center c2 and a third center c3 located in an adjacent first repeating unit RU1 and adjacent to the second center c2 in the second direction Y to the distance between the second center c2 and the third center c3 located in the same first repeating unit RU1 is greater than 1 and equal to or less than 1.2.

With continued reference to FIGS. 12A and 12B, in some embodiments, the orthographic projection of the twenty-first cathode selection pattern 821 on the base substrate 1 is located between the fifth pattern p5 in the corresponding first repeating unit RU1 and an eighth pattern p8 adjacent to the fifth pattern p5 in the second direction Y and in an adjacent first repeating unit RU1. The orthographic projection of the twenty-second cathode selection pattern 822 on the base substrate 1 is located between the fifth pattern p5 in the corresponding first repeating unit RU1 and a sixth pattern p6 adjacent to the fifth pattern p5 in the first direction X and in an adjacent first repeating unit RU1. The orthographic projection of the twenty-third cathode selection pattern 823 on the base substrate 1 is located between the fifth pattern p5 in the corresponding first repeating unit RU1 and the eighth pattern p8 in the corresponding first repeating unit RU1. The orthographic projection of the twenty-fourth cathode selection pattern 824 on the base substrate 1 is located between the seventh pattern p7 in the corresponding first repeating unit RU1 and the eighth pattern p8 in the corresponding first repeating unit RU1.

Referring to FIG. 12B, in some embodiments, at least one first repeating unit RU1 is configured with at least one corresponding support pattern 4. The corresponding support patterns 4 configured by each first repeating unit RU1 include: at least one of a twenty-first support pattern 421, and a twenty-second support pattern 422.

An orthographic projection of the twenty-first support pattern 421 on the base substrate 1 is located between the second pattern p2 in the corresponding first repeating unit RU1 and the third pattern p3 in the corresponding first repeating unit RU1.

An orthographic projection of the twenty-second support pattern 422 on the base substrate 1 is located between the third pattern p3 in the corresponding first repeating unit RU1 and a fourth pattern p4 adjacent to the third pattern p3 in the first direction X and in an adjacent first repeating unit RU1.

With continued reference to FIG. 12B, further optionally, the orthographic projection of the twenty-first support pattern 421 on the base substrate 1 is located between the fifth pattern p5 in the corresponding first repeating unit RU1 and the sixth pattern p6 in the corresponding first repeating unit RU1.

The orthographic projection of the twenty-second support pattern 422 on the base substrate 1 is located between the sixth pattern p6 in the corresponding first repeating unit RU1 and the seventh pattern p7 in the corresponding first repeating unit RU1.

In the embodiment of the present disclosure, given that a size of each cathode selection pattern 8 may be larger than that of each support pattern 4, a spacing between sub-pixels near each cathode selection pattern 8 may be designed to be relatively large, and a spacing between sub-pixels near each support pattern 4 may be designed to be relatively small.

The layout of the sub-pixels shown in FIGS. 12A and 12B may be regarded as obtained by keeping the first pattern p1, the third pattern p3, the fifth pattern p5 to the eighth pattern p8 in FIG. 6 still, moving the second pattern p2 towards a lower right direction by a distance, and moving the fourth pattern p4 towards a lower left direction by a distance.

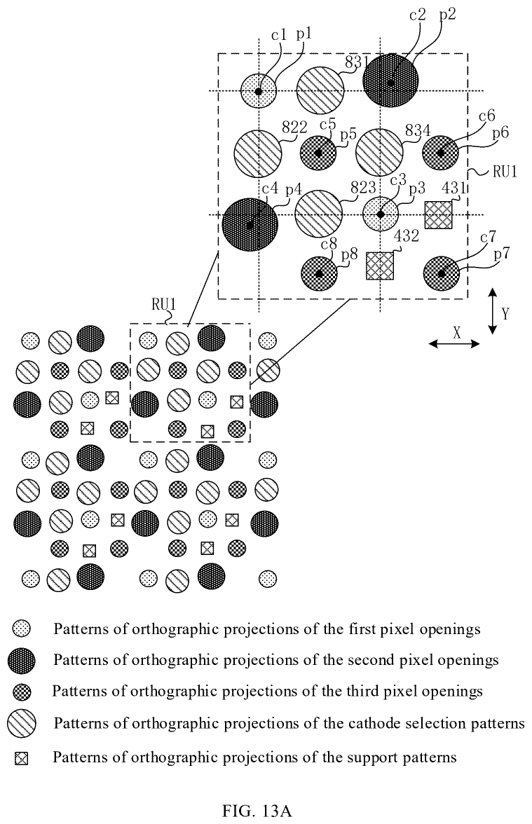

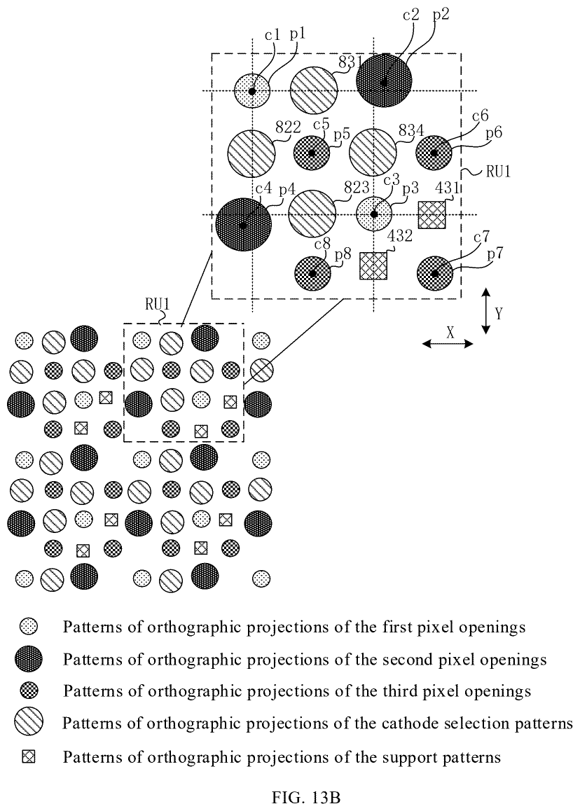

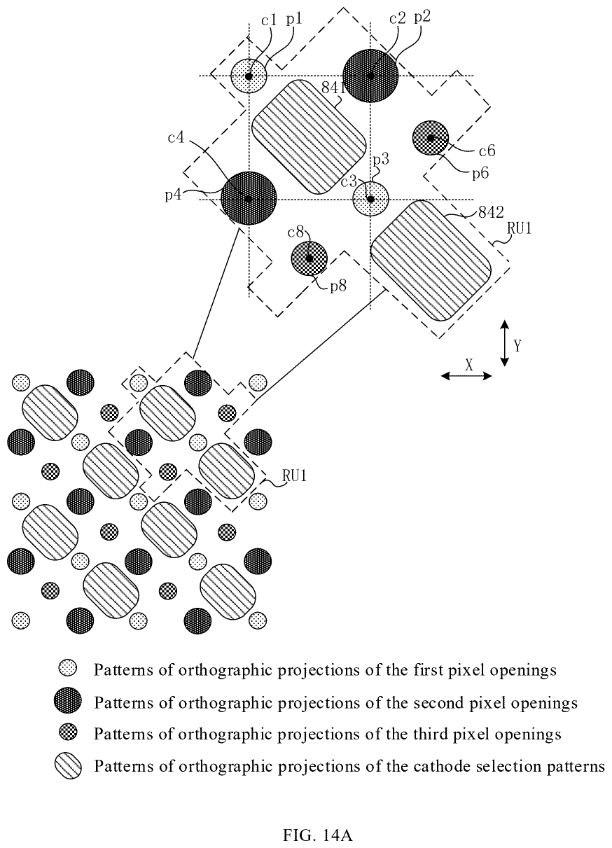

FIG. 13A is another schematic top view of a local region in a first display region 101 according to an embodiment of the present disclosure; FIG. 13B is a schematic top view of a local region with a support pattern in FIG. 13A. As another alternative, as shown in FIGS. 13A and 13B, in some embodiments, in each first repeating unit RU1, a minimum distance between the first pattern p1 and the second pattern p2 is greater than a minimum distance between the first pattern p1 and a second pattern p2 in an adjacent first repeating unit RU1 and adjacent to the first pattern p1 in the first direction X, a minimum distance between the first pattern p1 and the fourth pattern p4 is greater than a minimum distance between the first pattern p1 and a fourth pattern p4 located in an adjacent first repeating unit RU1 and adjacent to the first pattern p1 in the second direction Y, a minimum distance between the fourth pattern p4 and the third pattern p3 is greater than a minimum distance between the fourth pattern p4 and a third pattern p3 in an adjacent first repeating unit RU1 and adjacent to the fourth pattern p4 in the first direction X, and a minimum distance between the third pattern p3 and the second pattern p2 is greater than a minimum distance between the third pattern p3 and a second pattern p2 in an adjacent first repeating unit RU1 and adjacent to the third pattern p3 in the second direction Y.

The corresponding cathode selection patterns 8 configured by each first repeating unit RU1 include: at least one of a thirty-first cathode selection pattern 831, a thirty-second cathode selection pattern 832, a thirty-third cathode selection pattern 833, and a thirty-fourth cathode selection pattern 834.

An orthographic projection of the thirty-first cathode selection pattern 831 on the base substrate 1 is located between the first pattern p1 in the corresponding first repeating unit RU1 and the second pattern p2 in the corresponding first repeating unit RU1.

In the embodiment as shown in FIGS. 13A and 13B, there is a greater spacing between the first pattern p1 and the second pattern p2 located in the same first repeating unit RU1 as the first pattern p1, so that the thirty-first cathode selection pattern 831 may be designed at the greater spacing and may have a larger size, which is beneficial to improving the light transmittance of the first display region 101.

An orthographic projection of the thirty-second cathode selection pattern 832 on the base substrate 1 is located between the first pattern p1 in the corresponding first repeating unit RU1 and the fourth pattern p4 in the corresponding first repeating unit RU1.

In the embodiment as shown in FIGS. 13A and 13B, there is a greater spacing between the first pattern p1 and the fourth pattern p4 located in the same first repeating unit RU1 as the first pattern p1, so that the thirty-second cathode selection pattern 832 may be designed at the greater spacing and may have a larger size, which is beneficial to improving the light transmittance of the first display region 101.

An orthographic projection of the thirty-third cathode selection pattern 833 on the base substrate 1 is located between the third pattern p3 in the corresponding first repeating unit RU1 and the fourth pattern p4 in the corresponding first repeating unit RU1.

In the embodiment as shown in FIGS. 13A and 13B, there is a greater spacing between the third pattern p3 and the fourth pattern p4 located in the same first repeating unit RU1 as the first pattern p1, so that the thirty-third cathode selection pattern 833 may be designed at the greater spacing and may have a larger size, which is beneficial to improving the light transmittance of the first display region 101.

An orthographic projection of the thirty-fourth cathode selection pattern 834 on the base substrate 1 is located between the second pattern p2 in the corresponding first repeating unit RU1 and the third pattern p3 in the corresponding first repeating unit RU1.

In the embodiment as shown in FIGS. 13A and 13B, there is a greater spacing between the second pattern p2 and the third pattern p3 located in the same first repeating unit RU1 as the second pattern p2, so that the thirty-fourth cathode selection pattern 834 may be designed at the greater spacing and may have a larger size, which is beneficial to improving the light transmittance of the first display region 101.

Referring to FIGS. 13A and 13B, in some embodiments, in each first repeating unit RU1, a ratio of a distance between the first center c1 and the second center c2 to a distance between the first center c1 and a second center c2 in an adjacent first repeating unit RU1 and adjacent to the first center c1 in the first direction X is greater than 1 and equal to or less than 1.2; a ratio of a distance between the first center c1 and the fourth center c4 to a distance between the first center c1 and a fourth center c4 in an adjacent first repeating unit RU1 and adjacent to the first center c1 in the second direction Y is greater than 1 and equal to or less than 1.2; a ratio of a distance between the fourth center c4 and the third center c3 to a distance between the fourth center c4 and a third center c3 in an adjacent first repeating unit RU1 and adjacent to the fourth center c4 in the first direction X is greater than 1 and equal to or less than 1.2; a ratio of a distance between the third center c3 and the second center c2 to a distance between the third center c3 and a second center c2 in an adjacent first repeating unit RU1 and adjacent to the third center c3 in the second direction Y is greater than 1 and equal to or less than 1.2.

In some embodiments, four sides of the first quadrangle Q1 are all equal in length. That is, the first quadrangle Q1 is a rhombus, so that the thirty-first cathode selection pattern 831 to the thirty-fourth cathode selection pattern 834 are uniformly arranged on the four sides of the first quadrangle Q1.

With continued reference to FIGS. 13A and 13B, in some embodiments, the orthographic projection of the thirty-first cathode selection pattern 831 on the base substrate 1 is located between the fifth pattern p5 in the corresponding first repeating unit RU1 and an eighth pattern p8 adjacent to the fifth pattern p5 in the second direction Y and in an adjacent first repeating unit RU1. The orthographic projection of the thirty-second cathode selection pattern 832 on the base substrate 1 is located between the fifth pattern p5 in the corresponding first repeating unit RU1 and a sixth pattern p6 adjacent to the fifth pattern p5 in the first direction X and in an adjacent first repeating unit RU1. The orthographic projection of the thirty-third cathode selection pattern 833 on the base substrate 1 is located between the fifth pattern p5 in the corresponding first repeating unit RU1 and the eighth pattern p8 in the corresponding first repeating unit RU1. The orthographic projection of the thirty-fourth cathode selection pattern 834 on the base substrate 1 is located between the fifth pattern p5 in the corresponding first repeating unit RU1 and the sixth pattern p6 in the corresponding first repeating unit RU1.

Referring to FIG. 13B, in some embodiments, at least one first repeating unit RU1 is configured with at least one corresponding support pattern 4. The corresponding support patterns 4 configured by each first repeating unit RU1 include: at least one of a thirty-first support pattern 431, and a thirty-second support pattern 432.

An orthographic projection of the thirty-first support pattern 431 on the base substrate 1 is located between the third pattern p3 in the corresponding first repeating unit RU1 and a fourth pattern p4 adjacent to the third pattern p3 in the first direction X and in an adjacent first repeating unit RU1.

An orthographic projection of the thirty-second support pattern 432 on the base substrate 1 is located between the third pattern p3 in the corresponding first repeating unit RU1 and a second pattern p2 adjacent to the third pattern p3 in the second direction Y and in an adjacent first repeating unit RU1.

With continued reference to FIG. 13B, further optionally, the orthographic projection of the thirty-first support pattern 431 on the base substrate 1 is located between the sixth pattern p6 in the corresponding first repeating unit RU1 and the seventh pattern p7 in the corresponding first repeating unit RU1.

The orthographic projection of the thirty-second support pattern 432 on the base substrate 1 is located between the seventh pattern p7 in the corresponding first repeating unit RU1 and the eighth pattern p8 in the corresponding first repeating unit RU1.

In the embodiment of the present disclosure, given that a size of each cathode selection pattern 8 may be larger than that of each support pattern 4, a spacing between sub-pixels near each cathode selection pattern 8 may be designed to be relatively large, and a spacing between sub-pixels near each support pattern 4 may be designed to be relatively small.

The layout of the sub-pixels shown in FIGS. 13A and 13B may be regarded as obtained by keeping the first pattern p1, the third pattern p3, the fifth pattern p5 to the eighth pattern p8 in FIG. 6 still, moving the second pattern p2 towards an upper right direction by a distance, and moving the fourth pattern p4 towards a lower left direction by a distance.

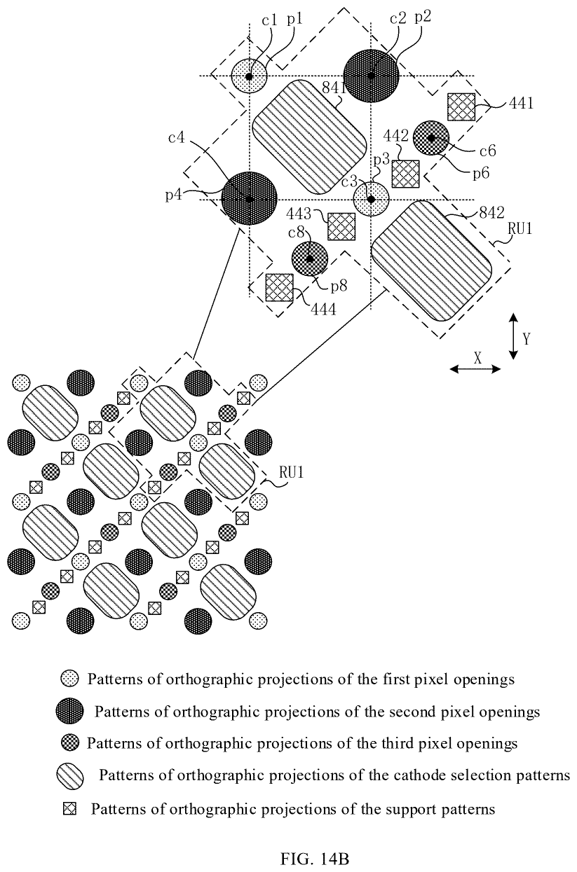

FIG. 14A is another schematic top view of a local region in a first display region 101 according to an embodiment of the present disclosure; FIG. 14B is a schematic top view of a local region with a support pattern in FIG. 14A. As another alternative, as shown in FIGS. 14A and 14B, in some embodiments, a line connecting the first center c1 of the first pattern p1 and the third center c3 of the third pattern p3 in each first repeating unit RU1 extends along a third direction.

Four centers, including the center of the third pattern p3 in the first repeating unit RU1, a center of a second pattern p2 adjacent to the third pattern p3 in the second direction Y and in an adjacent first repeating unit RU1, a center of a first pattern p1 adjacent to the third pattern p3 in the third direction and in an adjacent first repeating unit RU1, and a center of a fourth pattern p4 adjacent to the third pattern p3 in the first direction X and in an adjacent first repeating unit RU1, are sequentially connected to form a third quadrangle corresponding to the first repeating unit RU1.

The corresponding cathode selection patterns 8 configured by the first repeating unit RU1 include: at least one of a forty-first cathode selection pattern 841 and a forty-second cathode selection pattern 842.

An orthographic projection of the forty-first cathode selection pattern 841 on the base substrate 1 is located in a region surrounded by the first quadrangle Q1 corresponding to the first repeating unit RU1 and covers a center of the first quadrangle Q1.

In the embodiment as shown in FIGS. 14A and 14B, the region surrounded by the first quadrangle Q1 defined by the first center c1 to the fourth center c4 located in the same first repeating unit RU1 has a larger space, so that the forty-first cathode selection pattern 841 may be designed in the larger space and may have a larger size, which is beneficial to improving the light transmittance of the first display region 101.

An orthographic projection of the forty-second cathode selection pattern 842 on the base substrate 1 is located in a region surrounded by the third quadrangle corresponding to the first repeating unit RU1 and covers a center of the third quadrangle.

In the embodiment as shown in FIGS. 14A and 14B, the region surrounded by the third quadrangle defined by the third center c3 together with the first center c1, the second center c2 and the fourth center c4 in the other three adjacent first repeating units RU1 has a larger space, so that the forty-second cathode selection pattern 842 may be designed in the larger space and may have a larger size, which is beneficial to improving the light transmittance of the first display region 101.

In some embodiments, a length of the forty-first cathode selection pattern 841 in the first direction X is greater than the minimum distance between the first pattern p1 and the second pattern p2 in the corresponding first repeating unit RU1 in the first direction X.

A length of the forty-first cathode selection pattern 841 in the second direction Y is greater than the minimum distance between the first pattern p1 and the fourth pattern p4 in the corresponding first repeating unit RU1 in the second direction Y.

A length of the forty-second cathode selection pattern 842 in the first direction X is greater than the minimum distance between the first pattern p1 and the second pattern p2 in the corresponding first repeating unit RU1 in the first direction X.

A length of the forty-second cathode selection pattern 842 in the second direction Y is greater than the minimum distance between the first pattern p1 and the fourth pattern p4 in the corresponding first repeating unit RU1 in the second direction Y.

Unlike the above embodiments in which each first repeating unit RU1 includes the four third sub-pixels, each first repeating unit RU1 includes two third sub-pixels in the embodiment shown in FIGS. 14A and 14B. A pixel opening 3a corresponding to each third sub-pixel is a third pixel opening 3a, orthographic projections of the two third pixel openings 3a on the base substrate 1 are the sixth pattern p6 and the eighth pattern p8, respectively, the sixth pattern p6 and the first quadrangle Q1 corresponding to the same first repeating unit RU1 are arranged along the second direction Y, and the eighth pattern p8 and the first quadrangle Q1 corresponding to the same first repeating unit RU1 are arranged along the first direction X.

Referring to FIGS. 14A and 14B, a line connecting the second center c2 of the second pattern p2 and the fourth center c4 of the fourth pattern p4 in the same first repeating unit RU1 extends along a fourth direction, and at least one first repeating unit RU1 is configured with at least one corresponding support pattern 4.

The corresponding support patterns 4 configured by the first repeating unit RU1 include: at least one of a forty-first support pattern 441, a forty-second support pattern 442, a forty-third support pattern 443, and a forty-fourth support pattern 444.

An orthographic projection of the forty-fourth support pattern 441 on the base substrate 1 is located between the sixth pattern p6 in the corresponding first repeating unit RU1 and a first pattern p1 adjacent to the sixth pattern p6 in the fourth direction and in an adjacent first repeating unit RU1.

An orthographic projection of the forty-second support pattern 442 on the base substrate 1 is located between the sixth pattern p6 in the corresponding first repeating unit RU1 and the third pattern p3 in the corresponding first repeating unit RU1.

An orthographic projection of the forty-third support pattern 443 on the base substrate 1 is located between the eighth pattern p8 in the corresponding first repeating unit RU1 and the third pattern p3 in the corresponding first repeating unit RU1.

An orthographic projection of the forty-fourth support pattern 444 on the base substrate 1 is located between the eighth pattern p8 in the corresponding first repeating unit RU1 and a first pattern p1 adjacent to the eighth pattern p8 in the fourth direction and in an adjacent first repeating unit RU1.

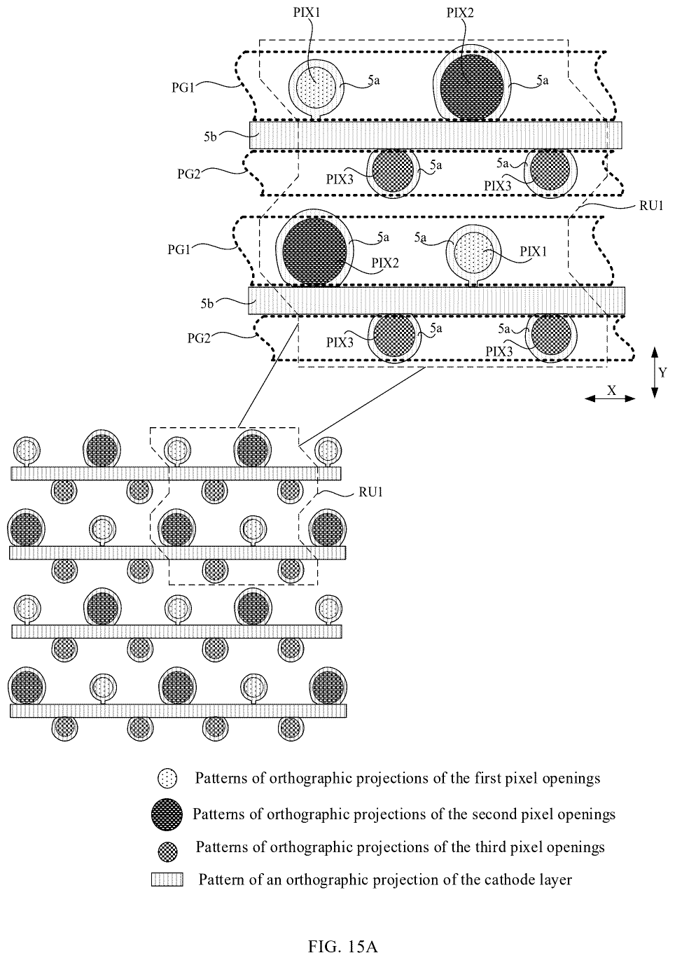

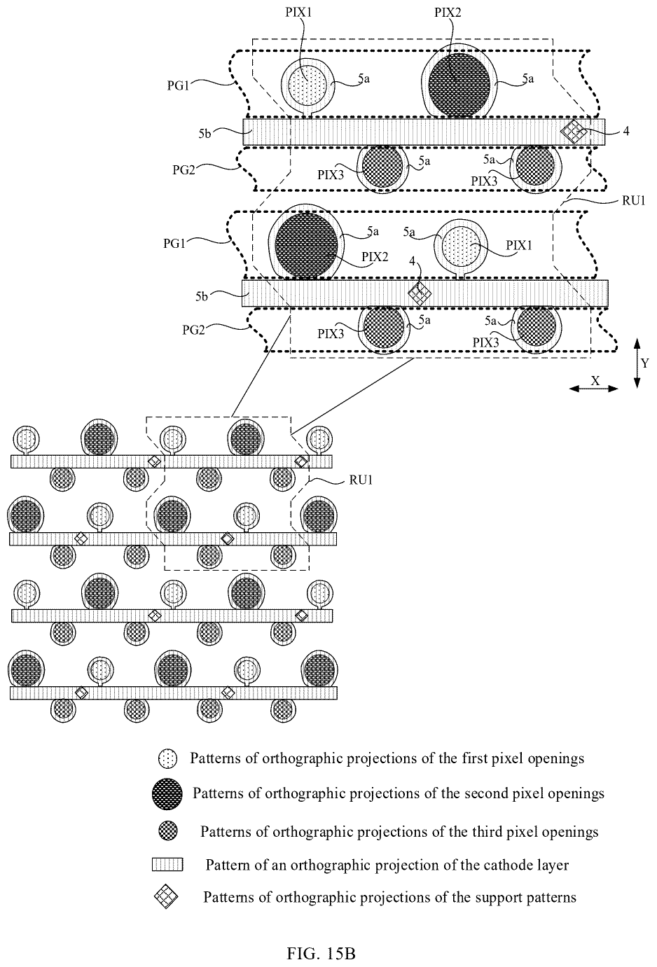

FIG. 15A is another schematic top view of a local region in a first display region 101 according to an embodiment of the present disclosure; FIG. 15B is a schematic top view of a local region with a support pattern in FIG. 15A. Unlike the above embodiment in which the cathode layer 5 is patterned by providing the cathode selection patterns 8 in the first display region 101, the cathode layer 5 may be patterned without the cathode selection patterns 8 in FIGS. 15A and 15B.

As one example, a cathode material film may be formed on a surface of a substrate to be processed through a deposition process, and then patterned through a laser cathode-removing process. Specifically, a cathode material in a laser-scanned region of the cathode material film is removed, and a cathode material in a laser-unscanned region remains, so as to obtain the patterned cathode layer 5. A pattern formed through the laser cathode-removing process has extremely high precision.

It should be noted that the case in which the “laser cathode-removing process” is adopted to realize the patterning of the cathode material film in the present disclosure is only one optional embodiment in the present disclosure, and does not limit the technical solution of the present disclosure. Other processes, such as an etching process or the like, may alternatively be employed in the present disclosure to achieve the patterning of the cathode material film.

In some embodiments, the cathode layer 5 includes: a plurality of cathode selection patterns 5a in one-to-one correspondence with the pixel openings 3a, an orthographic projection of each cathode selection pattern 5a on the base substrate 1 covers an orthographic projection of the corresponding pixel opening 3a on the base substrate 1, the cathode layer 5 further includes a plurality of cathode lines 5b sequentially arranged along the second direction Y, and the cathode selection patterns 5a are connected to the corresponding cathode lines 5b.

In some embodiments, the support patterns 4 are disposed in the first display region 101, and an orthographic projection of the cathode lines 5b on the base substrate 1 covers an orthographic projection of the support patterns 4 on the base substrate 1.

In the embodiment of the present disclosure, when the cathode layer 5 is located on a side of the support patterns 4 away from the base substrate 1 and the cathode material film is patterned by the “laser cathode-removing process”, given that the support patterns 4 affects a scanning path of laser, which may cause abnormal removing of the cathode material, the support patterns 4 are disposed at a position for bypassing the scanning path of the laser.

Alternatively, in order to avoid the influence of the support patterns 4 on the “laser cathode-removing process”, the support patterns 4 may alternatively be disposed on a side of the cathode layer 5 away from the base substrate 1. That is, the support patterns 4 are formed after the patterning of the cathode material film is completed.

In some embodiments, a plurality of sub-pixel groups are disposed in the first display region 101, and sequentially arranged along the second direction Y and include: one first sub-pixel sub-group PG1 and one second sub-pixel sub-group PG2 arranged in the second direction Y. The first sub-pixel sub-group PG1 includes first sub-pixels PIX1 and second sub-pixels PIX2 alternately arranged in the first direction X, and the second sub-pixel sub-group PG2 includes a plurality of third sub-pixels PIX3 sequentially arranged in the first direction X. The third sub-pixels PIX3 are arranged in a staggering way with the first sub-pixels PIX1 and the second sub-pixels PIX2 in the first direction X. The sub-pixel groups are in one-to-one correspondence with the cathode lines 5b, each cathode line 5b is located between the first sub-pixel sub-group PG1 and the second sub-pixel sub-group PG2 in the corresponding sub-pixel group, and is connected to the cathode selection patterns 5a corresponding to the first sub-pixels PIX1, the second sub-pixels PIX2 and the third sub-pixels PIX3 in the corresponding sub-pixel group.

That is, the cathode selection patterns 5a corresponding to all the sub-pixels in the same sub-pixel group are connected to the same cathode line 5b. By such design, the region covered by the cathode layer 5 has a smaller area, and a region corresponding to the hollowed-out structures 7 has a larger area, which is beneficial to improving the light transmittance of the first display region 101.

In some embodiments, the pixel opening 3a corresponding to each first sub-pixel PIX1 is a first pixel opening 3a, the pixel opening 3a corresponding to each second sub-pixel PIX2 is a second pixel opening 3a, and the pixel opening 3a corresponding to each third sub-pixel PIX3 is a third pixel opening 3a.

In the first display region 101, a pattern of an orthographic projection of each first pixel opening 3a on the base substrate 1 is an eleventh pattern, a pattern of an orthographic projection of each second pixel opening 3a on the base substrate 1 is a twelfth pattern, and a pattern of an orthographic projection of each third pixel opening 3a on the base substrate 1 is a thirteenth pattern.

A minimum distance between the thirteenth pattern and the eleventh pattern closest to each other in the same sub-pixel group is greater than a minimum distance between the thirteenth pattern and the twelfth pattern closest to each other in the same sub-pixel group. An orthographic projection of each support pattern 4 on the base substrate 1 is located between the thirteenth pattern and the eleventh pattern closest to each other in the same sub-pixel group and corresponding to the support pattern 4.

The above various structures in the first display region 101 shown in FIG. 6 to FIG. 15B are only some optional embodiments in the present disclosure, and do not limit the technical solution of the present disclosure. Other suitable layout of the sub-pixels, the cathode selection patterns 8 and the support patterns 4 in the first display region 101 may alternatively be adopted in the present disclosure, and are not enumerated here.

In some embodiments, each first sub-pixel PIX1 is a sub-pixel for emitting red light (referred to as a red sub-pixel), each second sub-pixel PIX2 is a sub-pixel for emitting blue light (referred to as a blue sub-pixel), and each third sub-pixel PIX3 is a sub-pixel for emitting green light (referred to as a green sub-pixel).

Further optionally, an area of the pixel opening 3a corresponding to each blue sub-pixel is larger than an area of the pixel opening 3a corresponding to each red sub-pixel, which is larger than an area of the pixel opening 3a corresponding to each green sub-pixel.

Alternatively, in practical applications, a shape and an area of the pixel opening 3a corresponding to each sub-pixel may be designed and adjusted in advance according to actual needs.

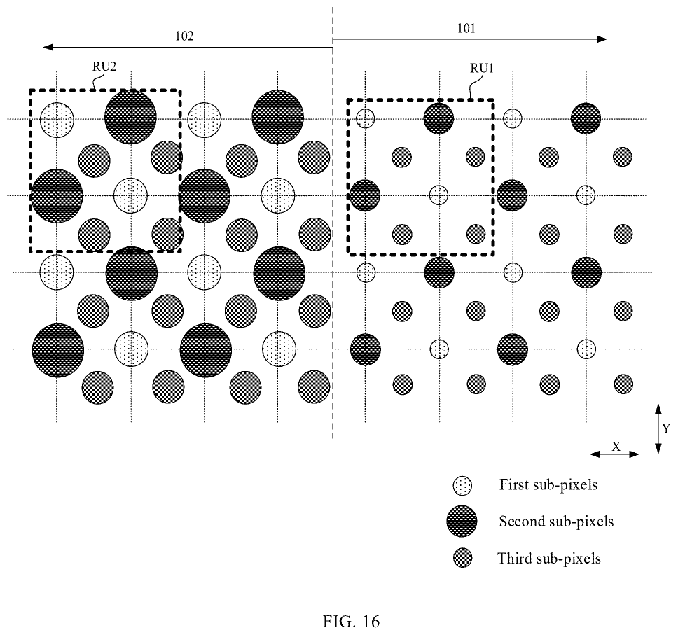

FIG. 16 is a schematic top view of a portion of a display substrate in the present disclosure. As shown in FIG. 16, in the embodiment of the present disclosure, each second repeating unit RU2 located in the second display region 102 may have the same sub-pixel arrangement as each first repeating unit RU1 in the first display region 101. As an example, each first repeating unit RU1 in the first display region 101 includes two first sub-pixels, two second sub-pixels and four third sub-pixels, that is, eight sub-pixels in total, as shown in FIG. 6, and each second repeating unit RU2 in the second display region 102 also includes two first sub-pixels, two second sub-pixels and four third sub-pixels, that is, eight sub-pixels in total, which are arranged in the same manner as the eight sub-pixels in each first repeating unit RU1.

In some embodiments, given that the light transmittance of the first display region 101 is improved as much as possible and the cathode selection patterns 8 are provided in the first repeating unit RU1, a size of each sub-pixel in the first repeating unit RU1 may be designed to be smaller than a size of the corresponding sub-pixel in the second repeating unit RU2, so that a spacing between any two adjacent sub-pixels in the first repeating unit RU1 is increased.

As an example, a size of the first sub-pixel in the first repeating unit RU1 is about 50% of a size of the first sub-pixel in the second repeating unit RU2, a size of the second sub-pixel in the first repeating unit RU1 is about 50% of a size of the second sub-pixel in the second repeating unit RU2, and a size of the third sub-pixel in the first repeating unit RU1 is about 50% of a size of the third sub-pixel in the second repeating unit RU2.

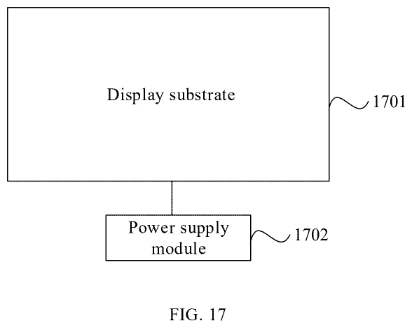

FIG. 17 is a schematic diagram of a display apparatus according to an embodiment of the present disclosure. As shown in FIG. 17, the present embodiment provides a display apparatus, including a display substrate 1701 and a power supply module 1702. The power supply module 1702 may be used to supply power to the display substrate 1701.

The display substrate 1701 in the embodiment of the present disclosure may adopt the display substrate provided in any one of the above embodiments, and the specific description of the display substrate 1701 may refer to the above embodiments, and details are not repeated herein.

The display substrate in the embodiment of the present disclosure may be: an OLED display substrate, or a QLED display substrate or the like. The display apparatus in the embodiment of the present disclosure may be: any product or component with a display function, such as a mobile phone, a tablet, a television, a display, a notebook computer, a digital photo frame, or a navigator or the like.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A display substrate, comprising:
a base substrate;
a pixel defining layer on a side of the base substrate and comprising a plurality of pixel openings;
a plurality of support patterns on a side of the pixel defining layer away from the base substrate; and
a cathode layer on a side of the pixel defining layer away from the base substrate, and comprising a plurality of hollowed-out structures, wherein an orthographic projection of the plurality of hollowed-out structures on the base substrate does not overlap with an orthographic projection of the plurality of pixel openings on the base substrate.

2. The display substrate of claim 1, wherein the orthographic projection of the plurality of hollowed-out structures on the base substrate does not overlap with an orthographic projection of the plurality of support patterns on the base substrate.

3. The display substrate of claim 1, further comprising:
a plurality of cathode selection patterns in one-to-one correspondence with the plurality of hollowed-out structures, wherein an orthographic projection of each cathode selection pattern on the base substrate at least partially overlaps with an orthographic projection of the corresponding hollowed-out structure on the base substrate.

4. The display substrate of claim 3, wherein an area of an orthographic projection of each of at least a part of the plurality of cathode selection patterns on the base substrate is greater than an area of an orthographic projection of each support pattern on the base substrate.

5. The display substrate of claim 3, wherein the display substrate comprises a first display region and a second display region at a periphery of the first display region, the plurality of hollowed-out structures and the plurality of cathode selection patterns are in the first display region, and a light transmittance of the first display region is greater than that of the second display region.

6. The display substrate of claim 5, wherein the plurality of support patterns are in the second display region and not in the first display region.

7. The display substrate of claim 6, wherein the plurality of support patterns are uniformly distributed in the second display region; or
the second display region comprises: a first sub-region close to and surrounding the first display region and a second sub-region on a side of the first sub-region away from the first display region, and a density of support patterns in the first sub-region is greater than that of support patterns in the second sub-region.

8. The display substrate of claim 5, wherein support patterns are in the first display region.

9. The display substrate of claim 8, further comprising: a plurality of first repeating units in the first display region and arranged in an array along a first direction and a second direction, wherein each first repeating unit comprises a plurality of sub-pixels, and each of at least a part of the plurality of first repeating units is configured with at least one support pattern of the plurality of support patterns; and
a ratio of the number of the plurality of sub-pixels in each first repeating unit configured with the at least one support pattern to the number of the at least one support pattern in the same first repeating unit is greater than or equal to 2 and less than or equal to 8.

10. The display substrate of claim 3, further comprising: a plurality of first repeating units in the first display region and arranged in an array along a first direction and a second direction, wherein each first repeating unit comprises a plurality of sub-pixels, and each of at least a part of the plurality of first repeating units is configured with at least one cathode selection pattern of the plurality of cathode selection patterns; and
a ratio of the number of the plurality of sub-pixels in each first repeating unit configured with the at least one cathode selection pattern to the number of the at least one cathode selection pattern in the same first repeating unit is greater than or equal to 2 and less than or equal to 8.

11. The display substrate of claim 8, further comprising: a plurality of first repeating units in the first display region and arranged in an array along a first direction and a second direction, wherein each first repeating unit comprises two first sub-pixels and two second sub-pixels, pixel openings corresponding to the two first sub-pixels are first pixel openings, and pixel openings corresponding to the two second sub-pixels are second pixel openings;
in each first repeating unit, patterns of orthographic projections of the first pixel openings of the two first sub-pixels on the base substrate are a first pattern and a third pattern, respectively, patterns of orthographic projections of the second pixel openings of the two second sub-pixels on the base substrate are a second pattern and a fourth pattern, respectively, and centers of the first pattern, the second pattern, the third pattern and the fourth pattern are a first center, a second center, a third center and a fourth center, respectively, which are sequentially connected to form a first quadrangle corresponding to the first repeating unit, and
at least one of the plurality of first repeating units each is configured with at least one corresponding cathode selection pattern, an orthographic projection of the at least one cathode selection pattern corresponding to each first repeating unit on the base substrate overlaps with a region surrounded by the first quadrangle corresponding to the first repeating unit.

12. The display substrate of claim 11, wherein in each first repeating unit, an extending direction of a line connecting the first center and the fourth center is parallel to the second direction, and an extending direction of a line connecting the second center and the third center is parallel to the second direction;
a minimum distance between the first pattern and the fourth pattern is greater than a minimum distance between the second pattern and the third pattern;
the at least one corresponding cathode selection pattern configured by the first repeating unit comprises: at least one of a first cathode selection pattern and a second cathode selection pattern;
an orthographic projection of the first cathode selection pattern on the base substrate is between the first pattern in the corresponding first repeating unit and the fourth pattern in the corresponding first repeating unit; and
an orthographic projection of the second cathode selection pattern on the base substrate is between the third pattern in the corresponding first repeating unit and a second pattern adjacent to the third pattern in the second direction and in an adjacent first repeating unit.

13-18. (canceled)

19. The display substrate of claim 11, wherein in each first repeating unit, a minimum distance between the second pattern and the third pattern is greater than a minimum distance between the second pattern and the first pattern;
a minimum distance between the fourth pattern and the third pattern is greater than a minimum distance between the fourth pattern and the first pattern;
the at least one corresponding cathode selection pattern configured by each first repeating unit comprises: at least one of an eleventh cathode selection pattern, a twelfth cathode selection pattern, a thirteenth cathode selection pattern, and a fourteenth cathode selection pattern;
an orthographic projection of the eleventh cathode selection pattern on the base substrate is between the second pattern in the corresponding first repeating unit and a first pattern adjacent to the second pattern in the first direction and in an adjacent first repeating unit;
an orthographic projection of the twelfth cathode selection pattern on the base substrate is between the second pattern in the corresponding first repeating unit and the third pattern in the corresponding first repeating unit;
an orthographic projection of the thirteenth cathode selection pattern on the base substrate is between the third pattern in the corresponding first repeating unit and the fourth pattern in the corresponding first repeating unit; and
an orthographic projection of the fourteenth cathode selection pattern on the base substrate is between the fourth pattern in the corresponding first repeating unit and a first pattern adjacent to the fourth pattern in the second direction and in an adjacent first repeating unit.

20-25. (canceled)

26. The display substrate of claim 11, wherein in each first repeating unit, a minimum distance between the second pattern and the first pattern is greater than a minimum distance between the second pattern and the third pattern;
a minimum distance between the fourth pattern and the first pattern is greater than a minimum distance between the fourth pattern and the third pattern;
the at least one corresponding cathode selection pattern configured by each first repeating unit comprises: at least one of an eleventh cathode selection pattern, a twelfth cathode selection pattern, a thirteenth cathode selection pattern, and a fourteenth cathode selection pattern;
an orthographic projection of the eleventh cathode selection pattern on the base substrate is between the first pattern in the corresponding first repeating unit and the second pattern in the corresponding first repeating unit;
an orthographic projection of the twelfth cathode selection pattern on the base substrate is between the first pattern in the corresponding first repeating unit and the fourth pattern in the corresponding first repeating unit;
an orthographic projection of the thirteenth cathode selection pattern on the base substrate is between the third pattern in the corresponding first repeating unit and a fourth pattern adjacent to the third pattern in the first direction and in an adjacent first repeating unit; and
an orthographic projection of the fourteenth cathode selection pattern on the base substrate is between the third pattern in the corresponding first repeating unit and a second pattern adjacent to the third pattern in the second direction and in an adjacent first repeating unit.

27-32. (canceled)

33. The display substrate of claim 11, wherein in each first repeating unit, a minimum distance between the first pattern and the second pattern is greater than a minimum distance between the first pattern and the fourth pattern;
a minimum distance between the third pattern and the second pattern is greater than a minimum distance between the third pattern and the fourth pattern;
the at least one corresponding cathode selection pattern configured by each first repeating unit comprises: at least one of an eleventh cathode selection pattern, a twelfth cathode selection pattern, a thirteenth cathode selection pattern, and a fourteenth cathode selection pattern;
an orthographic projection of the eleventh cathode selection pattern on the base substrate is between the first pattern in the corresponding first repeating unit and the second pattern in the corresponding first repeating unit;
an orthographic projection of the twelfth cathode selection pattern on the base substrate is between the second pattern in the corresponding first repeating unit and the third pattern in the corresponding first repeating unit;
an orthographic projection of the thirteenth cathode selection pattern on the base substrate is between the third pattern in the corresponding first repeating unit and a fourth pattern adjacent to the third pattern in the first direction and in an adjacent first repeating unit; and
an orthographic projection of the fourteenth cathode selection pattern on the base substrate is between the fourth pattern in the corresponding first repeating unit and a first pattern adjacent to the fourth pattern in the second direction and in an adjacent first repeating unit.

34-39. (canceled)

40. The display substrate of claim 11, wherein in each first repeating unit, a minimum distance between the first pattern and the fourth pattern is greater than a minimum distance between the first pattern and the second pattern;
a minimum distance between the third pattern and the fourth pattern is greater than a minimum distance between the third pattern and the second pattern;
the at least one corresponding cathode selection pattern configured by each first repeating unit comprises: at least one of an eleventh cathode selection pattern, a twelfth cathode selection pattern, a thirteenth cathode selection pattern, and a fourteenth cathode selection pattern;
an orthographic projection of the eleventh cathode selection pattern on the base substrate is between the second pattern in the corresponding first repeating unit and a first pattern adjacent to the second pattern in the first direction and in an adjacent first repeating unit;
an orthographic projection of the twelfth cathode selection pattern on the base substrate is between the first pattern in the corresponding first repeating unit and the fourth pattern in the corresponding first repeating unit;
an orthographic projection of the thirteenth cathode selection pattern on the base substrate is between the third pattern in the corresponding first repeating unit and the fourth pattern in the corresponding first repeating unit; and
an orthographic projection of the fourteenth cathode selection pattern on the base substrate is between the third pattern in the corresponding first repeating unit and a second pattern adjacent to the third pattern in the second direction and in an adjacent first repeating unit.

41-46. (canceled)

47. The display substrate of claim 11, wherein in each first repeating unit, a minimum distance between the first pattern and the second pattern is greater than a minimum distance between the second pattern and the third pattern;
a minimum distance between the first pattern and the fourth pattern is greater than the minimum distance between the second pattern and the third pattern;
a minimum distance between the fourth pattern and the third pattern is greater than the minimum distance between the second pattern and the third pattern;
the at least one corresponding cathode selection pattern configured by each first repeating unit comprises: at least one of a twenty-first cathode selection pattern, a twenty-second cathode selection pattern, a twenty-third cathode selection pattern, and a twenty-fourth cathode selection pattern;
an orthographic projection of the twenty-first cathode selection pattern on the base substrate is between the first pattern in the corresponding first repeating unit and the second pattern in the corresponding first repeating unit;
an orthographic projection of the twenty-second cathode selection pattern on the base substrate is between the first pattern in the corresponding first repeating unit and the fourth pattern in the corresponding first repeating unit;
an orthographic projection of the twenty-third cathode selection pattern on the base substrate is between the third pattern in the corresponding first repeating unit and the fourth pattern in the corresponding first repeating unit; and
an orthographic projection of the twenty-fourth cathode selection pattern on the base substrate is between the third pattern in the corresponding first repeating unit and a second pattern adjacent to the third pattern in the second direction and in an adjacent first repeating unit.

48-53. (canceled)

54. The display substrate of claim 11, wherein in each first repeating unit, a minimum distance between the first pattern and the second pattern is greater than a minimum distance between the first pattern and a second pattern in an adjacent first repeating unit and adjacent to the first pattern in the first direction;
a minimum distance between the first pattern and the fourth pattern is greater than a minimum distance between the first pattern and a fourth pattern in an adjacent first repeating unit and adjacent to the first pattern in the second direction;
a minimum distance between the fourth pattern and the third pattern is greater than a minimum distance between the fourth pattern and a third pattern in an adjacent first repeating unit and adjacent to the fourth pattern in the first direction;
a minimum distance between the third pattern and the second pattern is greater than a minimum distance between the third pattern and a second pattern in an adjacent first repeating unit and adjacent to the third pattern in the second direction;
the at least one corresponding cathode selection pattern configured by each first repeating unit comprises: at least one of a thirty-first cathode selection pattern, a thirty-second cathode selection pattern, a thirty-third cathode selection pattern, and a thirty-fourth cathode selection pattern;
an orthographic projection of the thirty-first cathode selection pattern on the base substrate is between the first pattern in the corresponding first repeating unit and the second pattern in the corresponding first repeating unit;
an orthographic projection of the thirty-second cathode selection pattern on the base substrate is between the first pattern in the corresponding first repeating unit and the fourth pattern in the corresponding first repeating unit;
an orthographic projection of the thirty-third cathode selection pattern on the base substrate is between the third pattern in the corresponding first repeating unit and the fourth pattern in the corresponding first repeating unit; and
an orthographic projection of the thirty-fourth cathode selection pattern on the base substrate is between the second pattern in the corresponding first repeating unit and the third pattern in the corresponding first repeating unit.

55-59. (canceled)

60. The display substrate of claim 11, wherein in the same first repeating unit, a line connecting the first center of the first pattern and the third center of the third pattern extends along a third direction;
four centers, comprising the center of the third pattern in the first repeating unit, a center of a second pattern adjacent to the third pattern in the second direction and in an adjacent first repeating unit, a center of a first pattern adjacent to the third pattern in the third direction and in an adjacent first repeating unit, and a center of a fourth pattern adjacent to the third pattern in the first direction and in an adjacent first repeating unit, are sequentially connected to form a third quadrangle corresponding to the first repeating unit;
the at least one corresponding cathode selection pattern configured by the first repeating unit comprises: at least one of a forty-first cathode selection pattern and a forty-second cathode selection pattern;
an orthographic projection of the forty-first cathode selection pattern on the base substrate is in a region surrounded by the first quadrangle corresponding to the first repeating unit and covers a center of the first quadrangle; and
an orthographic projection of the forty-second cathode selection pattern on the base substrate is in a region surrounded by the third quadrangle corresponding to the first repeating unit and covers a center of the third quadrangle.

61-63. (canceled)

64. The display substrate of claim 1, wherein the cathode layer comprises: a plurality of cathode selection patterns in one-to-one correspondence with the plurality of pixel openings, and an orthographic projection of each cathode selection pattern on the base substrate covers an orthographic projection of the corresponding pixel opening on the base substrate; and
the cathode layer further comprises a plurality of cathode lines sequentially arranged along the second direction, and the plurality of cathode selection patterns are connected to the corresponding cathode lines, respectively;
wherein the display substrate comprises a first display region and a plurality of sub-pixel groups in the first display region and sequentially arranged along the second direction, and the plurality of sub-pixel groups comprise: one first sub-pixel sub-group and one second sub-pixel sub-group arranged in the second direction;
the first sub-pixel sub-group comprises first sub-pixels and second sub-pixels alternately arranged in the first direction, the second sub-pixel sub-group comprises a plurality of third sub-pixels sequentially arranged in the first direction, and the plurality of third sub-pixels are arranged in a staggering way with the first sub-pixels and the second sub-pixels in the first direction; and
the plurality of sub-pixel groups are in one-to-one correspondence with the plurality of cathode lines, and each cathode line is between the first sub-pixel sub-group and the second sub-pixel sub-group in the corresponding sub-pixel group, and is connected to the cathode selection patterns corresponding to the first sub-pixels, the second sub-pixels and the plurality of third sub-pixels in the corresponding sub-pixel group;
wherein the plurality of support patterns are in the first display region, and an orthographic projection of each cathode line on the base substrate covers an orthographic projection of the corresponding support pattern on the base substrate; and
wherein the pixel opening corresponding to each first sub-pixel is a first pixel opening, the pixel opening corresponding to each second sub-pixel is a second pixel opening, and the pixel opening corresponding to each third sub-pixel is a third pixel opening;
in the first display region, a pattern of an orthographic projection of each first pixel opening on the base substrate is an eleventh pattern, a pattern of an orthographic projection of each second pixel opening on the base substrate is a twelfth pattern, and a pattern of an orthographic projection of each third pixel opening on the base substrate is a thirteenth pattern;
a minimum distance between the thirteenth pattern and the eleventh pattern closest to each other in the same sub-pixel group is greater than a minimum distance between the thirteenth pattern and the twelfth pattern closest to each other in the same sub-pixel group; and
an orthographic projection of each support pattern on the base substrate is between the thirteenth pattern and the eleventh pattern closest to each other in the same sub-pixel group and corresponding to the support pattern.

65-71. (canceled)
